(19) United States
(12) Patent Application Publication
(10) Pub. No.: US 2014/0104088 A1
(43) Pub. Date: Apr. 17, 2014

(54) DIFFERENTIAL SWITCH DRIVE CIRCUIT AND CURRENT STEERING DIGITAL-TO-ANALOG CONVERTER

(71) Applicant: PANASONIC CORPORATION, Osaka (JP)

(72) Inventors: Toshinobu NAGASAWA, Osaka (JP); Michiko YAMADA, Osaka (JP); Heiji IKOMA, Nara (JP)

(73) Assignee: PANASONIC CORPORATION, Osaka (JP)

(21) Appl. No.: 14/133,087

(22) Filed: Dec. 18, 2013

Related U.S. Application Data
(63) Continuation of application No. PCT/JP2011/006995, filed on Dec. 14, 2011.

(30) Foreign Application Priority Data
Jun. 23, 2011 (JP) 2011-139867

(51) Int. Cl. H03M 1/66; H03K 19/0185; H03K 3/013

(52) U.S. Cl. CPC H03M 1/66; H03K 3/013; H03K 19/0185
USPC 341/144; 327/109; 326/83

(57) ABSTRACT

A differential switch drive circuit includes a current source, a current control circuit including a pair of transistors having a pair of differential input terminals, a pair of differential output terminals for outputting differential output voltages, and a common connection node connected to the current source, and load elements each connected to a corresponding one of the pair of differential output terminals. Currents flowing through the pair of transistors are controlled so that the sum of currents flowing through the load elements during a steady state of the differential output voltages is different from the sum of currents flowing through the load elements during a transient state of the differential output voltages.

### CROSS-REFERENCE TO RELATED APPLICATIONS

This is a continuation of PCT International Application PCT/JP2011/006995 filed on Dec. 14, 2011, which claims priority to Japanese Patent Application No. 2011-139867 filed on Jun. 23, 2011. The entire disclosures of these applications are incorporated by reference herein.

### BACKGROUND

The present disclosure relates to differential switch drive circuits for driving a differential switch circuit, and current steering digital-to-analog converters including such a differential switch drive circuit.

In recent years, current steering digital-to-analog converters (DACs) have been utilized in, for example, video equipment, such as a plasma television, a liquid crystal television, an electro-luminescence television, a Blu-ray recorder, etc., and communication equipment employing a communication scheme, such as millimeter-wave communication, wireless local area network (LAN), power line communication (PLC), etc.

The current steering DAC includes a plurality of differential switch circuits, each differential switch circuit including two switch elements, and a plurality of constant current sources, corresponding to the respective differential switch circuits, each constant current source being connected to the two switch elements of the corresponding differential switch circuit. In each differential switch circuit, one of the two switch elements is selected based on digital data to allow a current to flow therethrough. The selected currents are added together for each polarity. A total current added together or a voltage occurring in a load element through which the total current is caused to flow is output as an analog signal. A differential switch drive circuit for driving a differential switch is connected to a control terminal of each differential switch circuit (see Japanese Patent No. 4202504).

The differential switch drive circuit typically has a configuration based on a complementary metal-oxide-semiconductor (CMOS) inverter configuration (see Japanese Patent No. 4202504, supra). A current steering DAC used in communication equipment needs to output a signal of several hundred megahertz to several gigaheltz. In order to allow the internal circuit to operate at high speed, a differential switch drive circuit including a current-mode logic (CML) circuit has been published (see K. Doris, et al., “A 12b 500 MS/s DAC with >70 dB SFDR up to 120 MHz in 0.18 μm CMOS,” ISSCC Digest of Technical Papers, pp. 116-117, February, 2005). The configuration of the CML circuit has also been described in other documents (see Japanese Unexamined Patent Publication No. 2006-80917).

FIG. 36 shows a differential switch drive circuit and a differential switch circuit which are used in a conventional current steering DAC for communication (see K. Doris, et al., supra). In the differential switch circuit 4, a constant current source 3 is connected to a common node VS to which switch elements 1 and 2 are connected. A gate voltage of an N-type metal-oxide-semiconductor (NMOS) transistor included in the constant current source 3 is represented by VBIAS. A current flowing through the switch element 1 is represented by IOUTA. A current flowing through the switch element 2 is represented by IOUTB. The differential switch drive circuit 505 has the following configuration: input terminals A and B to which non-inverted and inverted signals having opposite phases are input are linked to gate terminals of NMOS transistors 501 and 502, respectively; the NMOS transistors 501 and 502 have a common source terminal (common node), to which a constant current source 500 is connected; load elements 503 and 504 are connected between a positive power supply voltage VDD and drain terminals of the NMOS transistors 501 and 502, respectively; and connection points between the drain terminals of the NMOS transistors 501 and 502 and the load elements 503 and 504 are connected to output terminals X and Y, respectively. A drain current of the NMOS transistor 501 is represented by IA, and a drain current of the NMOS transistor 502 is represented by IB. The differential switch drive circuit 505 thus configured is a typical CML circuit (see Japanese Unexamined Patent Publication No. 2006-80917, supra). The output terminal X is connected to a gate terminal of an NMOS transistor included in the switch element 1, and the output terminal Y is connected to a gate terminal of an NMOS transistor included in the switch element 2.

In the differential switch drive circuit 505 and the differential switch circuit 4 thus configured, non-inverted and inverted signals having opposite phases are input to the input terminals A and B, respectively. Based on these input signals, a current of the constant current source 500 is divided by a control of the NMOS transistors 501 and 502 so that currents are caused to flow through the load elements 503 and 504, respectively. The resultant voltage drops allow for production of two-level voltages, i.e., a high-level voltage and a low-level voltage, which are output to the output terminals X and Y connected to the differential switch circuit 4. Based on the voltages of the output terminals X and Y, one of the switch elements 1 and 2 is selected to allow a current of the constant current source 3 to flow therethrough.

FIGS. 37A, 37B, and 37C show voltage or current waveforms of the terminals of FIG. 36. FIG. 37A shows example voltage waveforms of the input terminals A and B.

FIG. 37B shows waveforms of the drain currents IA and IB of the NMOS transistors 501 and 502. FIG. 37C shows voltage waveforms of the output terminals X and Y of the differential switch drive circuit 505 and input terminals of the differential switch circuit 4. As shown in FIG. 37B, cross points IP of the currents IA and IB are substantially the middle point of the high and low levels. As shown in FIG. 37C, cross points VP of the voltages of the output terminals X and Y are substantially the middle point of the high and low levels.

FIGS. 38A, 38B, 38C, 38D, and 38E show results of a simulation of voltage or current waveforms of the terminals of FIG. 36. Specifically, FIG. 38A shows voltage waveforms of the input terminals A and B. FIG. 38B shows waveforms of the drain currents IA and IB of the NMOS transistors 501 and 502 and a waveform of the sum values of the currents IA and IB. FIG. 38C shows voltage waveforms of the output terminals X and Y. FIG. 38D shows a voltage waveform of the node VS of the differential switch circuit 4. FIG. 38E shows waveforms of the currents IOUTA and IOUTB flowing through the switch elements 1 and 2.

As shown in FIG. 38B, the cross points IP of the currents IA and IB are substantially the middle point of the high and low levels. At the cross points, the sum values of the currents IA and IB are substantially equal to those in the steady state. As shown in FIG. 38C, the cross points VP of the voltages of the output terminals X and Y are also substantially the middle point of the high and low levels. As shown in FIG. 38D, both of the switch elements 1 and 2 are simultaneously off in the vicinity of the cross points of the voltages of the output terminals X and Y, so that the voltage of the node VS changes significantly. As shown in FIG. 38E, the waveforms of the currents IOUTA and IOUTB have poor transient response characteristics when changing from the low level to the high level, due to the influence of the potential change of the node VS.

In the differential switch drive circuit 505, when signals to the input terminals A and B are inverted, so that signals output to the output terminals X and Y change from the low level to the high level and from the high level to the low level, respectively, the cross point of the output voltages is in the vicinity of the middle point of the high and low levels due to voltage current conversion characteristics of the differential pair of the NMOS transistors 501 and 502 and the constant current source 500. Therefore, if the switch elements 1 and 2 include, for example, a MOS transistor, there are moments when both of the switch elements 1 and 2 are simultaneously off and when the sum value of the currents flowing through the switch elements 1 and 2 is extremely low with respect to the constant current source 3. This results in the absence of a path through which the current of the constant current source 3 flows. Therefore, if the constant current source 3 includes, for example, a MOS transistor, the potential of the connection node VS between the constant current source 3 and the switch elements 1 and 2 instantaneously changes significantly due to the infinite output impedance. The change of the connection node VS causes charging and discharging of the parasitic capacitance, which adversely affect the response characteristics of the output signal of the differential switch circuit 4. In addition, if the differential switch drive circuit 505 is used in a current steering DAC, a problem arises which causes a deterioration in distortion.

### SUMMARY

The present disclosure describes implementations for preventing a plurality of switch elements of a differential switch circuit from being simultaneously off, thereby improving response characteristics of an output signal of the differential switch circuit, and for improving a distortion which occurs when a differential switch circuit is used in a current steering DAC, and improving performance of the current steering DAC including the differential switch circuit.

An example differential switch drive circuit according to the present disclosure for driving a differential switch circuit including a first and a second switch element each having a terminal connected to a current source, includes a current source, at least one pair of transistors having a pair of differential input terminals, a pair of differential output terminals, and a common connection node connected to the current source, and load elements each connected to a corresponding one of the pair of differential output terminals. Signal voltages are applied to the pair of differential input terminals, and output voltages having a steady state in which the output voltages each take a respective one of two substantially constant values and a transient state in which the output voltages transition between the two substantially constant values, are output to the pair of differential output terminals, depending on voltages of the pair of differential input terminals. Currents flowing through the at least one pair of transistors are controlled so that the sum of values of currents flowing through the load elements during the steady state of the differential output voltages is different from the sum of values of currents flowing through the load elements during the transient state of the differential output voltages.

An example current steering DAC according to the present disclosure includes a decoder circuit configured to decode a digital signal, a plurality of differential switch circuits, and a plurality of differential switch drive circuits each configured to drive a corresponding one of the plurality of differential switch circuits. The current steering DAC adds currents each selected by a corresponding one of the plurality of differential switch circuits together to output an analog quantity. Each of the plurality of differential switch drive circuits includes a current control circuit to which a non-inverted and an inverted input terminal to which a signal decoded by the decoder circuit is applied, a non-inverted and an inverted output terminal, a first and a second load element connected to the inverted and non-inverted output terminals, respectively, and a current source, are connected. The current control circuit controls currents flowing through the two load elements based on input signals applied to the non-inverted and inverted input terminals so that a point where output voltages of each of the differential switch drive circuits connected to a pair of input terminals of a corresponding one of the plurality of differential switch circuits are equal to each other, is substantially shifted from the middle voltage of a dc output voltage range of the output voltages.

The differential switch drive circuit of the present disclosure can achieve high-speed operation, improve response characteristics of an output signal of the differential switch circuit, and improve a distortion when used in a current steering DAC.

### BRIEF DESCRIPTION OF THE DRAWINGS

FIG. 1 is a block diagram showing a configuration of a differential switch drive circuit and a differential switch circuit according to a first embodiment of the present disclosure.

FIGS. 2A, 2B, and 2C are diagrams showing voltage or current waveforms of terminals shown in FIG. 1.

FIG. 3 is a circuit diagram showing a specific example of the differential switch drive circuit of FIG. 1.

FIGS. 4A, 4B, 4C, and 4D are diagrams showing voltage or current waveforms of terminals shown in FIG. 3.

FIG. 5 is a circuit diagram showing another specific example of the differential switch drive circuit of FIG. 1.

FIGS. 6A, 6B, 6C, and 6D are diagrams showing voltage or current waveforms of terminals shown in FIG. 5.

FIG. 7 is a circuit diagram showing still another specific example of the differential switch drive circuit of FIG. 1.

FIGS. 8A, 8B, 8C, and 8D are diagrams showing voltage or current waveforms of terminals shown in FIG. 7.

FIG. 9 is a block diagram showing a configuration of a differential switch drive circuit according to a second embodiment of the present disclosure.

FIGS. 10A and 10B are circuit diagrams each showing a specific example of a delay circuit shown in FIG. 9.

FIGS. 11A, 11B, and 11C are circuit diagrams each showing a specific example of a logic unit having the NAND function shown in FIG. 9.

FIGS. 12A, 12B, and 12C are circuit diagrams each showing a specific example of a logic unit having the NOR function shown in FIG. 9.

FIGS. 13A, 13B, 13C, and 13D are diagrams showing voltage or current waveforms of terminals shown in FIG. 9, where the logic unit has the NAND function.

FIGS. 14A, 14B, 14C, and 14D are diagrams showing voltage or current waveforms of terminals shown in FIG. 9, where the logic unit has the NOR function.

FIG. 15 is a circuit diagram showing a specific example of the differential switch drive circuit of FIG. 9.

FIG. 16 is a block diagram showing a configuration of a differential switch drive circuit according to a third embodiment of the present disclosure.

FIGS. 17A, 17B, 17C, and 17D are diagrams showing voltage or current waveforms of terminals shown in FIG. 16, where the logic unit has the NAND function.

FIGS. 18A, 18B, 18C, and 18D are diagrams showing voltage or current waveforms of terminals shown in FIG. 16, where the logic unit has the NOR function.

FIG. 19 is a circuit diagram showing a specific example of the differential switch drive circuit of FIG. 16.

FIG. 20 is a circuit diagram showing another specific example of the differential switch drive circuit of FIG. 16.

FIG. 21 is a circuit diagram showing still another specific example of the differential switch drive circuit of FIG. 16.

FIG. 22 is a circuit diagram showing still another specific example of the differential switch drive circuit of FIG. 16.

FIG. 23 is a circuit diagram showing still another specific example of the differential switch drive circuit of FIG. 16.

FIG. 24 is a circuit diagram showing still another specific example of the differential switch drive circuit of FIG. 16.

FIG. 25 is a block diagram showing a configuration of a differential switch drive circuit and a differential switch circuit according to a fourth embodiment of the present disclosure.

FIGS. 26A and 26B are circuit diagrams each showing a specific example of a CML circuit shown in FIG. 25.

FIG. 27 is a block diagram showing a configuration of a differential switch drive circuit and a differential switch circuit according to a fifth embodiment of the present disclosure.

FIGS. 28A, 28B, 28C, and 28D are diagrams showing voltage or current waveforms of terminals shown in FIG. 27.

FIG. 29 is a circuit diagram showing a specific example of the differential switch drive circuit of FIG. 27.

FIGS. 30A, 30B, 30C, and 30D are diagrams showing voltage or current waveforms of terminals shown in FIG. 29.

FIG. 31 is a circuit diagram showing another specific example of the differential switch drive circuit of FIG. 27.

FIGS. 32A, 32B, 32C, 32D, and 32E are diagrams showing results of a simulation of voltage or current waveforms of terminals shown in FIG. 31.

FIG. 33 is a block diagram showing a configuration of a differential switch drive circuit and a differential switch circuit according to a sixth embodiment of the present disclosure.

FIG. 34 is a block diagram showing a configuration of a current steering DAC according to a seventh embodiment of the present disclosure.

FIG. 35 is a diagram showing a configuration of a millimeter-wave communication system according to an eighth embodiment of the present disclosure.

FIG. 36 is a circuit diagram showing a configuration of a conventional differential switch drive circuit and differential switch circuit.

FIGS. 37A, 37B, and 37C are diagrams showing voltage or current waveforms of terminals shown in FIG. 36.

FIGS. 38A, 38B, 38C, 38D, and 38E are diagrams showing results of a simulation of voltage or current waveforms of terminals shown in FIG. 36.

### DETAILED DESCRIPTION

Embodiments of the present disclosure will be described in detail below with reference to the accompanying drawings.

### First Embodiment

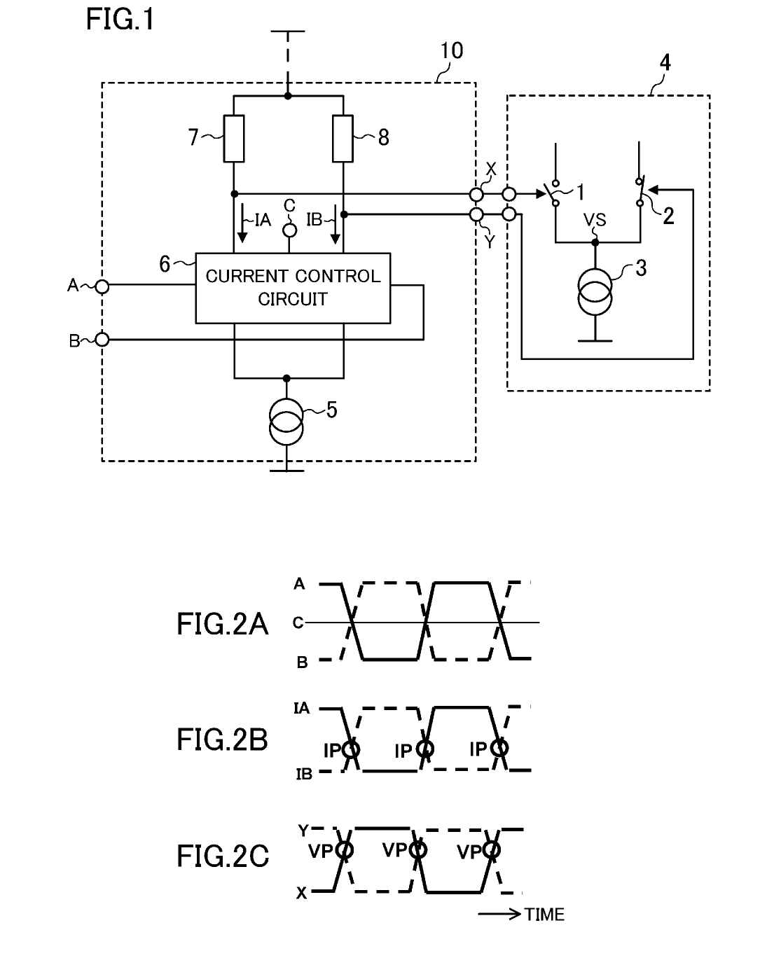

FIG. 1 is a diagram showing a configuration according to a first embodiment of the present disclosure. A differential switch circuit 4 shown in FIG. 1 has the same configuration as that of the conventional art. A differential switch drive circuit 10 has the following configuration: a current control circuit 6 has input terminals A and B to which non-inverted and inverted signals having opposite phases are input, and in addition, a control terminal C; a constant current source 5 is connected to the current control circuit 6; and a current of the constant current source 5 is divided by a control of the three terminals A, B, and C. Currents IA and IB obtained by division controlled by the current control circuit 6 are caused to change their current values when the input terminals A and B are switched between the high level and the low level. As a result of the control of the three terminals, a point where the values of the currents IA and IB cross each other in a transition phase during which the current IA goes from the high level to the low level and the current IB goes from the low level to the high level, is shifted from the middle point of the high and low levels. A point where the values of the currents IA and IB cross each other in a transition phase during which the current IA goes from the low level to the high level and the current IB goes from the high level to the low level, is also shifted from the middle point of the high and low levels. The currents IA and IB are caused to flow through load elements 7 and 8 connected to the current control circuit 6, to generate voltages of the output terminals X and Y, which are connected to respective corresponding input terminals of the differential switch circuit 4.

FIGS. 2A, 2B, and 2C show voltage or current waveforms of the terminals in the first embodiment of the present disclosure. FIG. 2A shows example voltage waveforms of the terminals A, B, and C. FIG. 2B shows waveforms of the currents IA and IB obtained by division controlled by the current control circuit 6. FIG. 2C shows voltage waveforms of the output terminals X and Y of the differential switch drive circuit 10 and the input terminals of the differential switch circuit 4. As shown in FIGS. 2B and 2C, cross points IP of the currents IA and IB obtained by division controlled by the current control circuit 6 take a value which is shifted from the middle point of the high and low levels. By causing the currents IA and IB to flow through the load elements 7 and 8, cross points VP of the voltage waveforms of the output terminals X and Y also take a value which is shifted from the middle point of the high and low levels. Note that, in the configuration of FIG. 1, the load elements 7 and 8 may be connected to either the power supply or the ground.

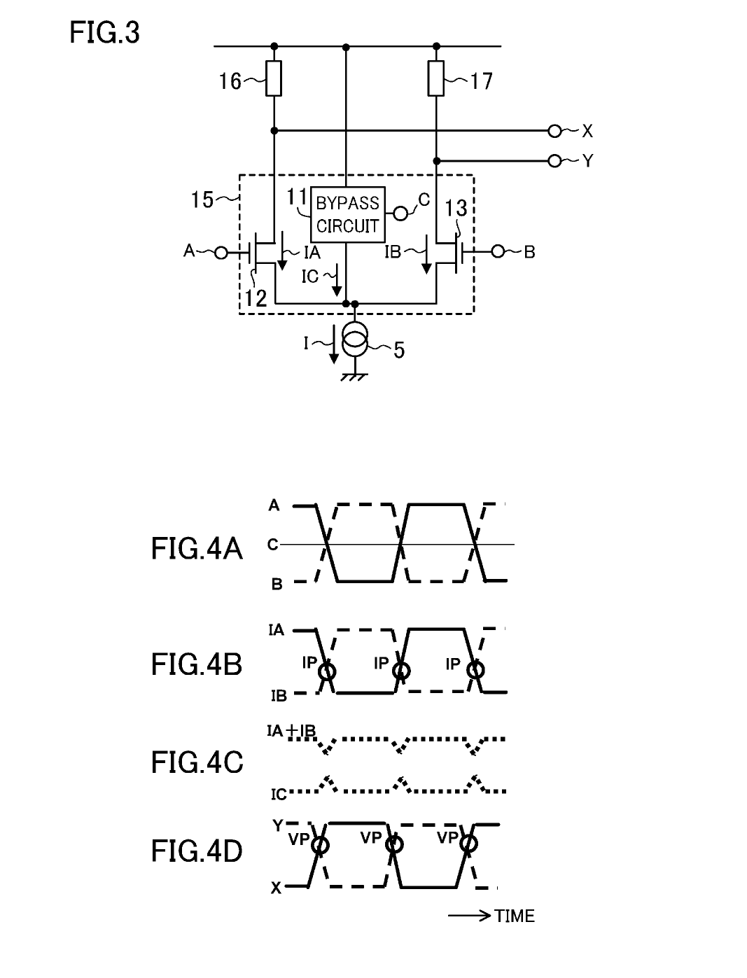

FIG. 3 shows an example circuit configuration according to the first embodiment of the present disclosure. As shown in FIG. 3, the circuit configuration includes NMOS transistors 12 and 13 which have a common source terminal. A non-inverted input to an input terminal A is applied to a gate terminal of the NMOS transistor 12, and an inverted input to an input terminal B is applied to a gate terminal of the NMOS transistor 13. A constant current source 5 is connected to the common source terminal of the NMOS transistors 12 and 13. Load elements 16 and 17 are connected to drain terminals of the NMOS transistors 12 and 13, respectively, at one end thereof, and to a power supply at the other end thereof. A bypass circuit 11 which is controlled through the control terminal C is connected to the common source terminal of the NMOS transistors 12 and 13. Connection points between the NMOS transistors 12 and 13 and the load elements 16 and 17 are connected to the output terminals X and Y, respectively. Note that the bypass circuit 11 and the NMOS transistors 12 and 13 form a current control circuit 15, which corresponds to the current control circuit 6 of FIG. 1.

An operation of this example circuit configuration of the first embodiment of the present disclosure will be described with reference to FIGS. 4A, 4B, 4C, and 4D which show voltage or current waveforms of the terminals. FIG. 4A shows example voltage waveforms of the terminals A, B, and C. FIG. 4B shows waveforms of drain currents IA and IB of the NMOS transistors 12 and 13. FIG. 4C shows a waveform of a current IC flowing through the bypass circuit 11 and a waveform of sum values of the currents IA and IB. FIG. 4D shows voltage waveforms of the output terminals X and Y of the differential switch drive circuit. The bypass circuit 11 performs a control so that a larger amount of current flows at cross points, and therefore, the sum values of the currents IA and IB in the transient state are lower than those in the steady state. Therefore, cross points IP of the currents are shifted to a value which is lower than the middle point of the high and low levels. Cross points VP of the voltage waveforms of the output terminals X and Y are shifted to a value which is higher than the middle point of the high and low levels.

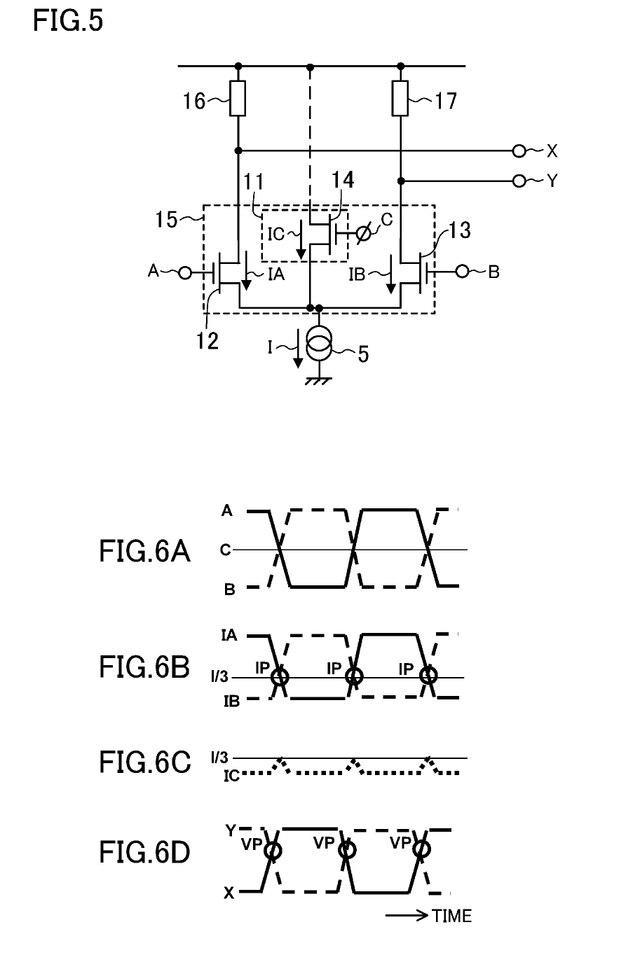

FIG. 5 shows another example circuit configuration according to the first embodiment of the present disclosure. As shown in FIG. 5, the circuit configuration includes NMOS transistors 12, 13, and 14 which have a common source terminal. A non-inverted input to an input terminal A is applied to a gate terminal of the NMOS transistor 12, an inverted input to an input terminal B is applied to a gate terminal of the NMOS transistor 13, and a DC voltage is applied to a gate terminal of the NMOS transistor 14 which serves as a control terminal C. A constant current source 5 is connected to the common source terminal of the NMOS transistors 12, 13, and 14. Load elements 16 and 17 are connected to drain terminals of the NMOS transistors 12 and 13, respectively, at one end thereof, and to a power supply at the other end thereof. A drain terminal of the NMOS transistor 14 is electrically connected to the power supply to which the load elements 16 and 17 are connected so that a drain current flows through the drain terminal of the NMOS transistor 14. Connection points between the NMOS transistors 12 and 13 and the load elements 16 and 17 are connected to output terminals X and Y, respectively. Note that the NMOS transistors 12, 13, and 14 form a current control circuit 15, which corresponds to the current control circuit 6 of FIG. 1.

An operation of this example circuit configuration of the first embodiment of the present disclosure will be described with reference to FIGS. 6A, 6B, 6C, and 6D which show voltage or current waveforms of the terminals. FIG. 6A shows example voltage waveforms of the terminals A, B, and C. FIG. 6B shows waveforms of drain currents IA and IB of the NMOS transistors 12 and 13. FIG. 6C shows a waveform of a drain current IC of the NMOS transistor 14. FIG. 6D shows voltage waveforms of the output terminals X and Y of the differential switch drive circuit 10 and input terminals of a differential switch circuit 4. As shown in FIG. 6A, it is assumed that non-inverted and inverted control voltages are applied to the input terminals A and B, respectively, and a DC value which is the middle value of the high and low levels of the input terminals A and B is applied to the control terminal C. Here, it is also assumed that the NMOS transistors 12, 13, and 14 have the same transistor size. In this case, as shown in FIGS. 6B and 6C, the drain currents of the NMOS transistors 12, 13, and 14 are each ⅓ of a current I of the constant current source 5 at points where the voltages of the terminals A, B, and C cross each other in a transition phase during which the voltages of the input terminals A and B change from the high level to the low level or from the low level to the high level. Moreover, if the transistor size is determined so that the current flowing through the NMOS transistor 14 is substantially zero when the voltages of the input terminals A and B are in the steady state, the high-level value, low-level value, and cross-point value of the currents IA and IB are I, zero, and I/3, respectively. In other words, the current cross point IP is not the middle point of the high and low levels, and is shifted to a value which is lower than the middle point. Thus, by causing the currents IA and IB obtained by division based on the voltages of the terminals A, B, and C to flow through the load elements 16 and 17, as shown in FIG. 6D cross points VP of the voltage waveforms of the output terminals X and Y have a voltage which is ⅔ of an amplitude width between the high and low levels, i.e., is shifted to a value which is higher than the middle point. Note that the voltage applied to the gate terminal of the NMOS transistor 14 preferably takes a DC value between the high and low levels of the voltages of the input terminals A and B. Instead of the DC value, for example, a control voltage which has a peak when the voltages of the input terminals A and B change from the high level to the low level or from the low level to the high level may be applied to the gate terminal of the NMOS transistor 14. Although NMOS transistors are used in the above example, the NMOS transistors may be replaced with PMOS transistors, where the power supply and the ground are interchanged. In this case, obviously, the cross point of the voltages of the output terminals X and Y is lower than the middle point of the amplitude between the high and low levels.

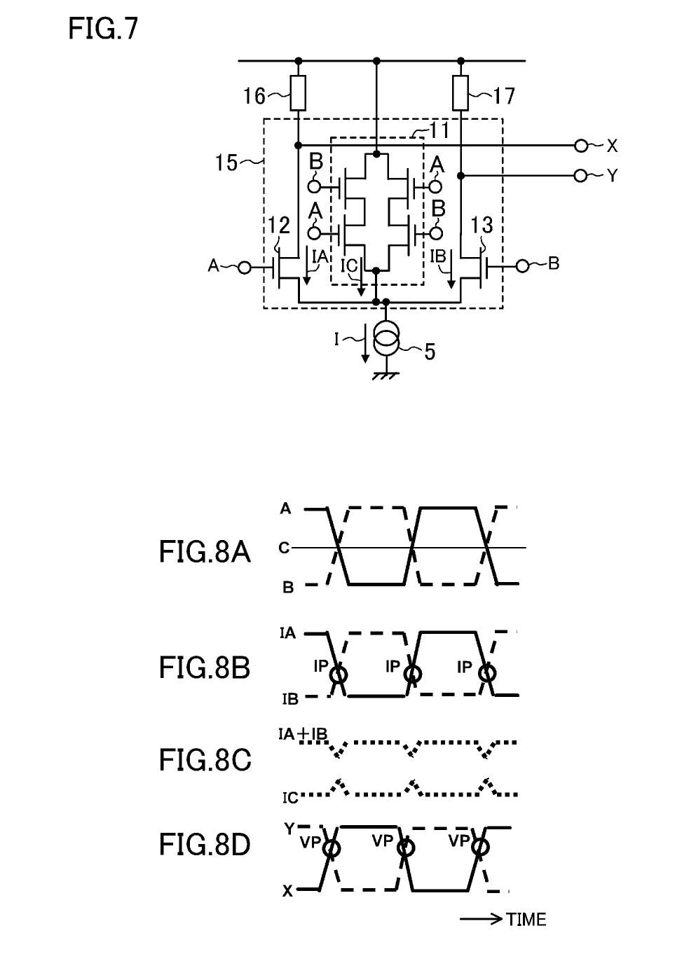

FIG. 7 shows still another example circuit configuration according to the first embodiment of the present disclosure. In FIG. 7, the single NMOS transistor 14 included in the bypass circuit 11 of FIG. 5 is replaced with four NMOS transistors. Gate terminals of the four NMOS transistors are connected to the input terminals A and B. As a result, a current IC flows through the bypass circuit 11 during a transition phase of input signals to the terminals A and B.

FIGS. 8A, 8B, 8C, and 8D are diagrams showing voltage or current waveforms of the terminals of FIG. 7. These figures are similar to FIGS. 4A-4D and will not be described.

According to the first embodiment, a differential switch drive circuit can be configured using a CML circuit (a circuit in which a current of a constant current source is controlled using a plurality of control terminals so that currents flow through load elements to generate output voltages), which is suitable for high-speed operation. Therefore, a plurality of switch elements included in the differential switch circuit can be prevented from being simultaneously off, whereby response characteristics of the output of the differential switch circuit can be improved.

### Second Embodiment

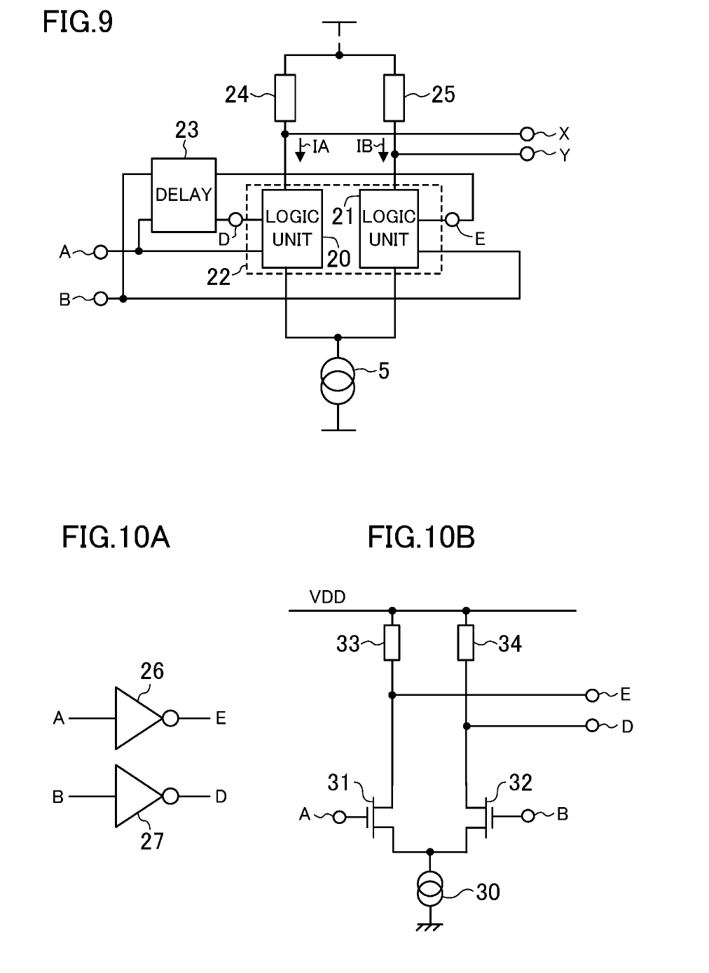

FIG. 9 is a diagram showing a configuration of a differential switch drive circuit according to a second embodiment of the present disclosure. In FIG. 9, a current control circuit 22 including logic units 20 and 21 has input terminals A and B to which non-inverted and inverted signals having opposite phases are input, and in addition, two or more control terminals (e.g., D and E). Signals of the input terminals A and B are input via a delay circuit 23 to the control terminals D and E. A constant current source 5 is connected to the current control circuit 22. A current of the constant current source 5 is divided by a control of the terminals A, B, D, and E. Currents IA and IB obtained by division controlled by the current control circuit 22 change their current values when the input terminals A and B are switched between the high level and the low level. A point where the values of the currents IA and IB cross each other in a transition phase during which the current IA goes from the high level to the low level and the current IB goes from the low level to the high level, takes a value which is shifted from the middle point of the high and low levels. A point where the values of the currents IA and IB cross each other in a transition phase during which the current IA goes from the low level to the high level and the current IB goes from the high level to the low level, is also shifted from the middle point of the high and low levels. The currents IA and IB are caused to flow through load elements 24 and 25, respectively, which are connected to the current control circuit 22 to generate voltages at the output terminals X and Y.

FIGS. 10A and 10B show example configurations of the delay circuit 23. FIG. 10A is an example functional block diagram showing the delay circuit 23. The signal of the input terminal A is inverted by an inverter 26 before being supplied to the control terminal E. The signal of the input terminal B is inverted by an inverter 27 before being supplied to the control terminal D. FIG. 10B shows the typical CML circuit described in the BACKGROUND section. The CML circuit includes a constant current source 30, NMOS transistors 31 and 32, and load elements 33 and 34. Non-inverted and inverted signals are applied to the input terminals A and B, whereby inverted outputs E and D are obtained, respectively. A delay amount is based on a parasitic capacitance, a current amount, etc. occurring during the course of the output inversion operation.

Note that FIGS. 10A and 10B show examples of the delay circuit 23. Any configuration that has a delay function may be employed. For example, in order to provide a delay amount, a time constant may be provided using a capacitor and a resistor at some point in the signal path. Alternatively, a plurality of the configurations of FIGS. 10A and 10B may be serially connected together. A DC value which is between the high and low levels may be applied to one of the input terminals A and B.

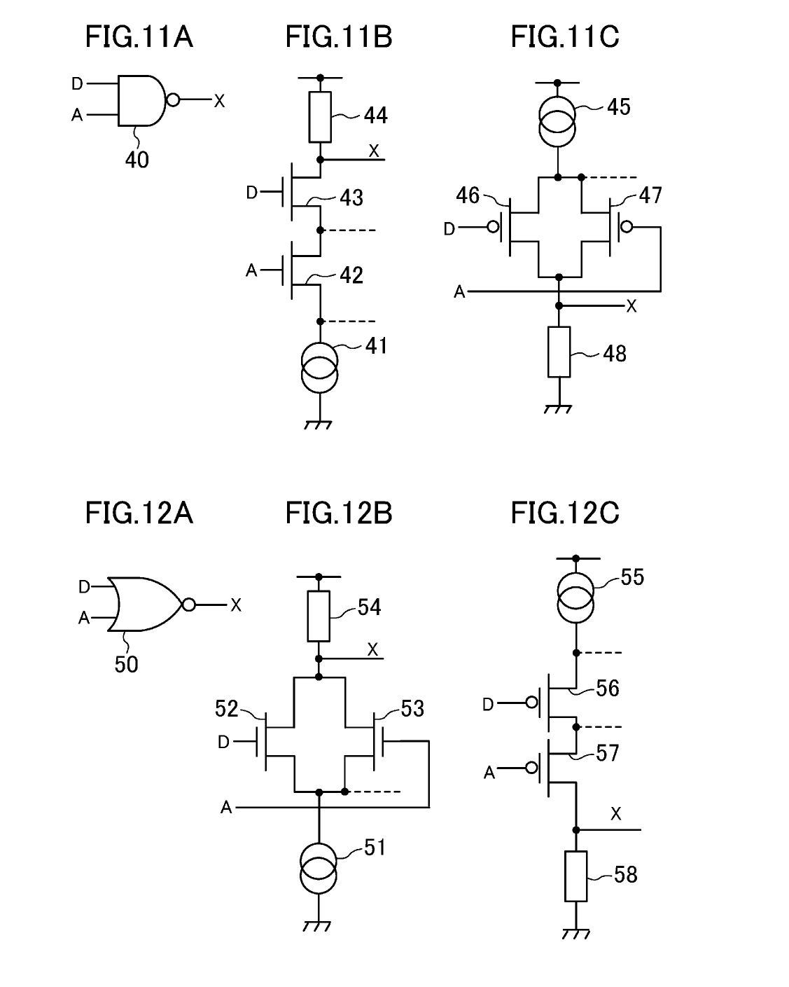

FIGS. 11A, 11B, and 11C show example configurations of the logic units 20 and 21. FIG. 11A is an example functional block diagram showing a NAND circuit 40 which serves as each of the logic units 20 and 21. FIG. 11B shows an example circuit including NMOS transistors which provide the NAND function. FIG. 11C shows an example circuit including PMOS transistors which provides the NAND function. In FIG. 11B, a portion in which NMOS transistors 42 and 43 are vertically stacked corresponds to the example circuit configuration of the logic units 20 and 21 of FIG. 9. In such a configuration, a current of a current source 41 is controlled at gate terminals of the NMOS transistors 42 and 43 so that only when both of the gate terminals are at the high level, the current of the current source 41 is caused to flow through a load element 44 connected to a power supply, whereby the low level is output. The high level is output during the other control operations. In FIG. 11C, a configuration in which source terminals of PMOS transistors 46 and 47 are connected together and drain terminals thereof are connected together corresponds to the example circuit configuration of the logic units 20 and 21 of FIG. 9. In such a configuration, a current of a current source 45 is controlled at gate terminals of the PMOS transistors 46 and 47 so that only when both of the gate terminals are at the high level, a current flowing through a load element 48 connected to a ground potential is stopped, whereby the low level is output. The high level is output during the other control operations.

Similarly, FIGS. 12A, 12B, and 12C show example configurations of the logic units 20 and 21. FIG. 12A is an example functional block diagram showing a NOR circuit 50 which serves as each of the logic units 20 and 21. FIG. 12B shows an example circuit configuration including NMOS transistors which provides the NOR function. FIG. 12C shows an example circuit including PMOS transistors which provides the NOR function. In FIG. 12B, a configuration in which source terminals of NMOS transistors 52 and 53 are connected together and drain terminals thereof are connected together corresponds to the example circuit configuration of the logic units 20 and 21 of FIG. 9. In such a configuration, a current of a current source 51 is controlled at gate terminals of the NMOS transistors 52 and 53 so that only when both of the gate terminals are at the low level, a current flowing through a load element 54 connected to a power supply is stopped, whereby the high level is output. The low level is output during the other control operations. In FIG. 12C, a portion in which PMOS transistors 56 and 57 are vertically stacked corresponds to the example circuit configuration of the logic units 20 and 21 of FIG. 9. In such a configuration, a current of a current source 55 is controlled at gate terminals of the PMOS transistors 56 and 57 so that only when both of the gate terminals are at the low level, a current of the current source 55 is caused to flow through a load element 58 connected to a ground potential, whereby the high level is output. The low level is output during the other control operations.

Note that dotted-line portions shown in FIGS. 11B, 11C, 12B, and 12C indicate bypass paths through which the currents of the constant current sources 41, 45, 51, and 55 are caused to flow when the currents flowing to the load elements 44, 48, 54, and 58 are stopped, i.e., bypass paths through which the currents bypass the load elements 44, 48, 54, and 58.

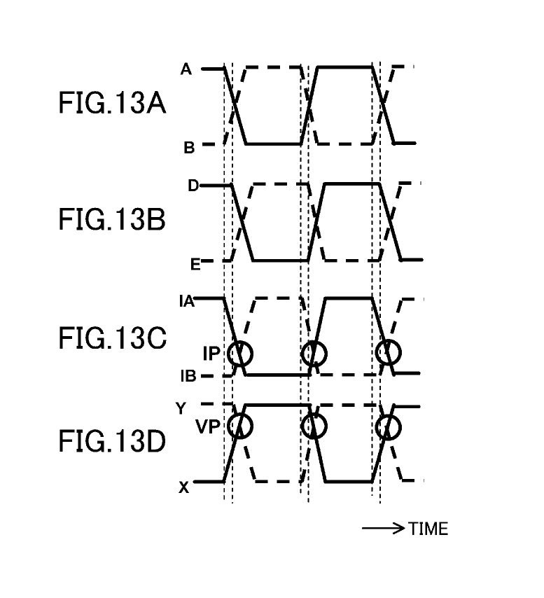

An operation of the differential switch drive circuit of the second embodiment of the present disclosure in which the NAND function (power supply-side load) is provided to the logic units 20 and 21, will be described with reference to FIGS. 13A, 13B, 13C, and 13D. FIG. 13A shows voltage waveforms of the input terminals A and B. FIG. 13B shows voltage waveforms of the control terminals D and E. FIG. 13C shows waveforms of the currents IA and IB obtained by division controlled by the current control circuit 22. FIG. 13D shows voltage waveforms of the output terminals X and Y. As shown in FIGS. 13A and 13B, non-inverted and inverted voltages are applied to the input terminals A and B, respectively, and signals of the input terminals A and B are delayed by the delay circuit 23 before being applied to the control terminals D and E, respectively. The logic units 20 and 21 both have the NAND function, and therefore, the current IA flows only when the terminals A and D are both at the high level, and the current IB flows only when the terminals B and E are both at the high level. Such a logic causes cross points IP of the currents IA and IB to be shifted to a value which is lower than the middle point of the high and low levels of the currents as shown in FIG. 13C, and causes cross points VP of the voltages of the output terminals X and Y to be shifted to a value which is higher than the middle point of the high and low levels of the output voltages as shown in FIG. 13D.

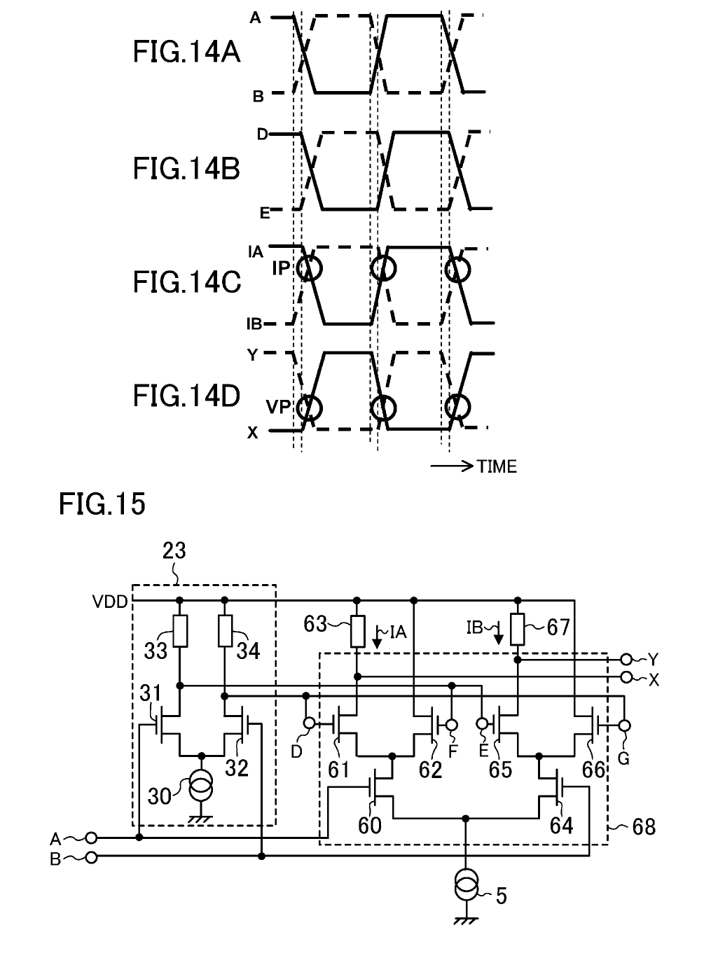

Also, an operation of the differential switch drive circuit of the second embodiment of the present disclosure in which the NOR function is provided to the logic units 20 and 21, will be described with reference to FIGS. 14A, 14B, 14C, and 14D. As shown in FIG. 14C, the logic units 20 and 21 both have the NOR function (power supply-side load), and therefore, the current IA is stopped only when the terminals A and D are both at the low level, and the current IB is stopped only when the terminal B and E are both at the low level. Such a logic causes cross points IP of the currents IA and IB to be shifted to a value which is higher than the middle point of the high and low levels of the currents as shown in FIG. 14C, and causes cross points VP of the voltages of the output terminals X and Y to be shifted to a value which is lower than the middle point of the high and low levels of the output voltages as shown in FIG. 14D.

As described above, according to this embodiment, the use of the NAND function causes the cross point VP of the voltages of the output terminals X and Y to be shifted to a higher value, and the use of the NOR function causes the cross point VP of the voltages of the output terminals X and Y to be shifted to a lower value.

FIG. 15 shows an example differential switch drive circuit according to the second embodiment of the present disclosure. In FIG. 15, a dotted-line portion 23 indicates the delay circuit of FIGS. 10A and 10B, and a dotted-line portion 68 indicates a current control circuit including NMOS transistors 60, 61, 62, 64, 65, and 66. The vertical stacks of the NMOS transistors 60 and 61 and the NMOS transistors 64 and 65 have the NAND function of FIG. 11B. The NMOS transistors 62 and 66 have a role in causing a current to bypass load elements 63 and 67 in the absence of the current flow of the load elements 63 and 67. Drain terminals of the NMOS transistors 61 and 65 are connected to the load elements 63 and 67, respectively, and the connection points are used as output terminals X and Y. Input terminals A and B are connected to gate terminals of the NMOS transistors 60 and 64, respectively, of a current control circuit 68 and gate terminals of NMOS transistors 31 and 32, respectively, of the delay circuit 23. Terminals D and E which are outputs of the delay circuit 23 are connected to gate terminals of the NMOS transistors 61 and 65, respectively. Control voltages of the terminals E and D which are signals having phases opposite to those of control signals of the terminals D and E, are input to gate terminals F and G of the NMOS transistors 62 and 66, respectively. The circuit thus configured has the NAND function in the logic unit, and therefore, the terminals thereof have voltage and current waveforms similar to those shown in FIGS. 13A-13D. Therefore, cross points of the voltages of the output terminals X and Y are shifted to a higher value.

Note that the configuration of FIG. 15 is merely an example. The logic unit may have the configurations shown in FIGS. 11A-11C and FIGS. 12A-12C or other configurations having the same function. The delay circuit 23 may have any other configuration that provides a delay amount instead of the configuration of FIG. 10B. Although the NMOS transistors 62 and 66 are used to cause a current to bypass the load elements 63 and 67, this bypass circuit may be removed if an element having a finite output impedance can be used to secure a stable operation. When the NMOS transistors 62 and 66 are used, the control voltages having phases opposite to those of the terminals D and E are applied in FIG. 15, or alternatively, a DC value between the high and low levels of the control voltages of the terminals D and E may be applied.

According to the second embodiment, a differential switch drive circuit can be configured using a CML circuit (a circuit in which a current of a constant current source is controlled using a plurality of control terminals so that currents flow through load elements to generate output voltages), which is suitable for high-speed operation. Therefore, a plurality of switch elements included in the differential switch circuit can be prevented from being simultaneously off, whereby response characteristics of the output of the differential switch circuit can be improved. The amount of the shift of the cross point of the outputs can be changed, depending on the amount of the delay of the delay circuit, leading to an increase in design flexibility.

### Third Embodiment

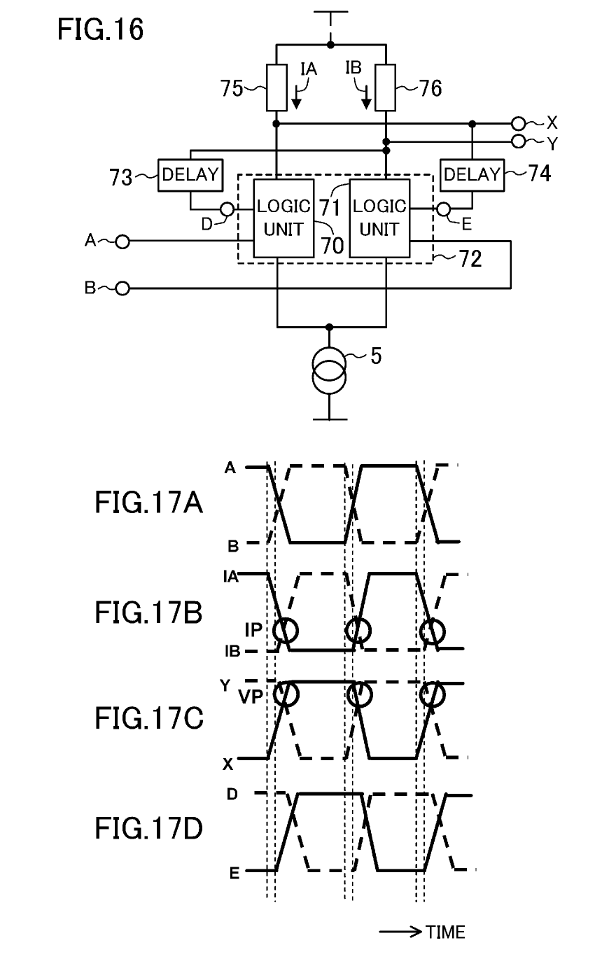

FIG. 16 is a diagram showing a configuration of a differential switch drive circuit according to a third embodiment of the present disclosure. In FIG. 16, a current control circuit 72 including logic units 70 and 71 has input terminals A and B to which non-inverted and inverted signals having opposite phases are input, and in addition, two or more control terminals (e.g., D and E). Signals which are obtained through the logic units 71 and 70 based on the signals at the input terminals B and A, are input directly or via delay circuits 73 and 74 to the control terminals D and E, respectively. A constant current source 5 is connected to the current control circuit 72, and a current of the constant current source 5 is divided by a control of the four terminals A, B, D, and E. Currents IA and IB obtained by division controlled by the current control circuit 72 are caused to change their current values when the input terminals A and B are switched between the high level and the low level. A point where the values of the currents IA and IB cross each other in a transition phase during which the current IA goes from the high level to the low level and the current IB goes from the low level to the high level, is shifted from the middle point of the high and low levels. A point where the values of the currents IA and IB cross each other in a transition phase during which the current IA goes from the low level to the high level and the current IB goes from the high level to the low level, is also shifted from the middle point of the high and low levels. The currents IA and IB are caused to flow through load elements 75 and 76 connected to the current control circuit 72, to generate voltages at output terminals X and Y. The logic units 70 and 71 and the delay circuits 73 and 74 each have an internal configuration similar to that of the second embodiment.

An operation of the differential switch drive circuit of the third embodiment of the present disclosure in which the NAND function (power supply-side load) is provided to the logic units 70 and 71, will be described with reference to FIGS. 17A, 17B, 17C, and 17D. FIG. 17A shows voltage waveforms of the input terminals A and B. FIG. 17B shows waveforms of the currents IA and IB obtained by division controlled by the current control circuit 72. FIG. 17C shows voltage waveforms of the output terminals X and Y. FIG. 17D shows voltage waveforms of the control terminals D and E. As shown in FIGS. 17A and 17B, when a voltage going from the high level to the low level is input to the input terminal A and a voltage going from the low level to the high level is input to the input terminal B, in the logic unit 70 which has been controlled to cause a current to flow until then because the terminals A and D have been at the high level the current IA is decreased by a control of the NAND function as the terminal A goes to the low level. The voltage of the output terminal X increases, following the decrease of the current IA, with a delay amount occurring in the logic unit 70. The voltage of the output terminal X is applied via the delay circuit 74 to the control terminal E. The voltage of the control terminal E increases with a delay amount occurring due to circuit delays of the logic unit 70 and the delay circuit 74 with respect to the voltage of the input terminal B having a phase opposite to that of the voltage of the input terminal A. A current flows through the logic unit 71, following the voltage of the terminal E, and the voltage of the output terminal Y decreases with a delay amount occurring in the logic unit 71. The voltage of the output terminal Y is applied via the delay circuit 73 to the control terminal D of the logic unit 70. Complemental operations to this series of operations are performed for the voltage of the input terminal B going from the high level to the low level and the voltage of the input terminal A going from the low level to the high level. By repetition of these operations, cross points IP of the currents IA and IB are shifted to a value which is lower than the middle point of the high and low levels of the currents as shown in FIG. 17B, and cross points VP of the voltages of the output terminals X and Y are shifted to a value which is higher than the middle point of the high and low levels of the output voltages as shown in FIG. 17C.

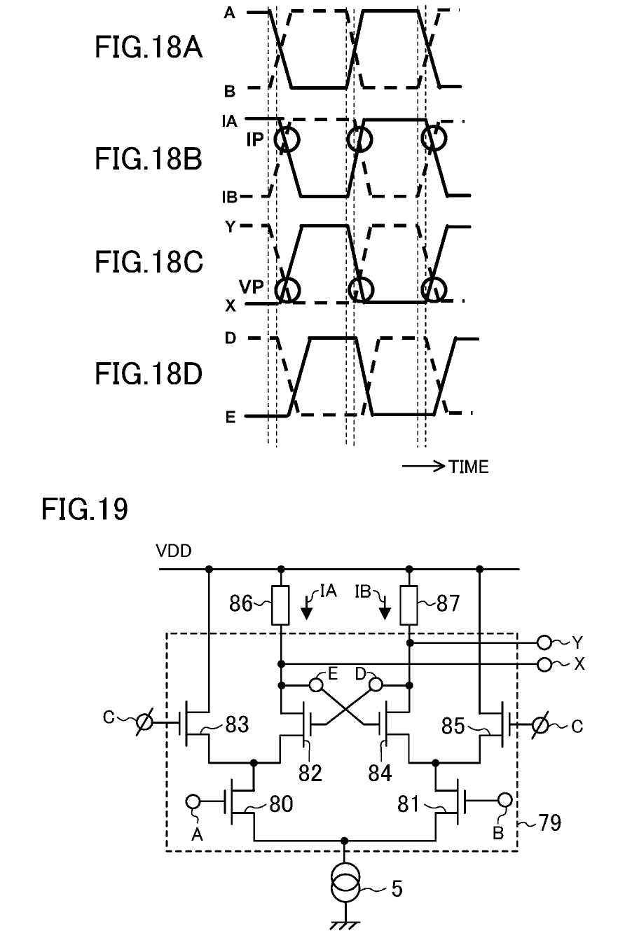

An operation of the differential switch drive circuit of the third embodiment of the present disclosure in which the NOR function is provided to the logic units 70 and 71 is shown in FIGS. 18A, 18B, 18C, and 18D. Cross points IP of the currents IA and IB obtained by division controlled by the current control circuit 72 are shifted to a value which is higher than the middle point of the high and low levels of the currents as shown in FIG. 18B, and cross points VP of the voltages of the output terminals X and Y are shifted to a value which is lower than the middle point of the high and low levels of the output voltages as shown in FIG. 18C.

FIGS. 19, 20, 21, 22, 23, and 24 show example circuits of the differential switch drive circuit of the third embodiment of the present disclosure.

In FIG. 19, a dotted-line portion 79 indicates a current control circuit including NMOS transistors 80-85. The vertical stacks of the NMOS transistors 80 and 82 and the NMOS transistors 81 and 84 have the NAND function of FIG. 11B. The NMOS transistors 83 and 85 have a role in causing a current to bypass load elements 86 and 87 in the absence of the current flow of the load elements 86 and 87. Drain terminals of the NMOS transistors 82 and 84 are connected to the load elements 86 and 87, respectively, and the connection points are used as output terminals X and Y, respectively. The output terminals Y and X are connected to gate terminals D and E of the NMOS transistors 82 and 84, respectively, and circuits corresponding to the delay circuits 73 and 74 of FIG. 16 are removed. A DC value between the high and low levels of voltages of the control terminals D and E is applied to the NMOS transistors 83 and 85 for bypass.

The circuit configured as shown in FIG. 19 has the NAND function in the logic unit, and has, at terminals thereof, voltage or current waveforms similar to those shown in FIGS. 17A-17D. Therefore, cross points of voltages of the output terminals X and Y are shifted to a higher voltage. Note that, as can be seen from this example circuit, the cross points of the output voltages can be shifted due to a delay amount which occurs due to a parasitic capacitance etc. of the circuit itself, without providing a delay circuit.

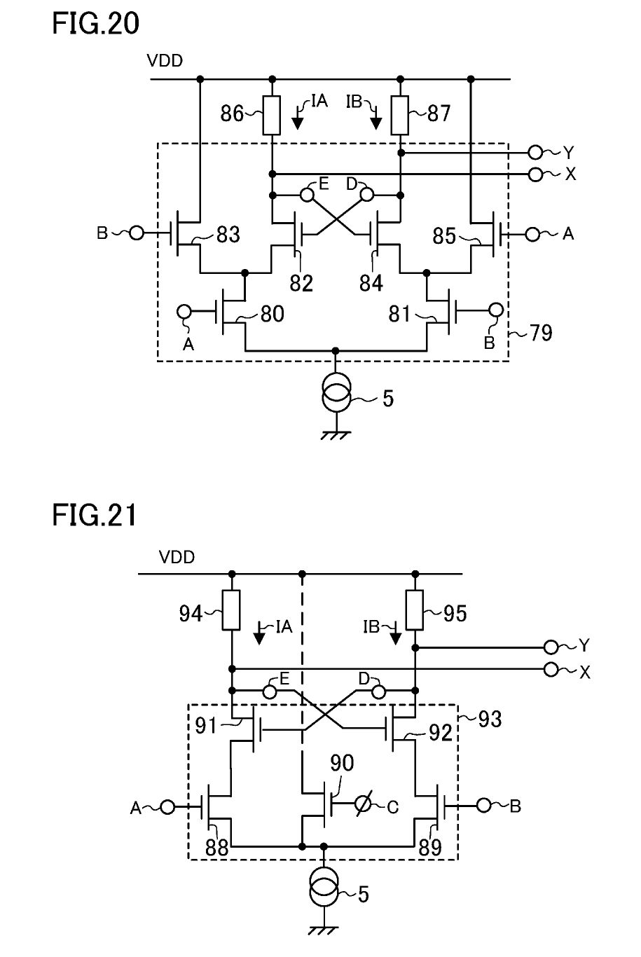

FIG. 20 shows a variation of the example circuit of FIG. 19 in which the voltages of the input terminals B and A are connected to gate terminals of the NMOS transistors 83 and 85 for bypass, respectively. The NMOS transistors 83 and 85 serve as a bypass circuit during the transition phase of signals of the input terminals A and B. Currents flowing through the NMOS transistors 83 and 85 can be stopped during the steady-state phase.

FIG. 21 is a variation of the example circuit of FIG. 19. A current control circuit 93 of FIG. 21 has, instead of the NMOS transistors 83 and 85, a bypass circuit in which an NMOS transistor 90, and NMOS transistors 88 and 89 having gate terminals to which input terminals A and B are connected, have a common source terminal. NMOS transistors 91 and 92 and load elements 94 and 95 of FIG. 21 correspond to the NMOS transistors 82 and 84 and the load elements 86 and 87 of FIG. 19. Similar to FIG. 19, such a configuration has voltage or current waveforms similar to those of FIGS. 17A-17D at terminals thereof, i.e., cross points of voltages of output terminals X and Y are shifted to a higher value.

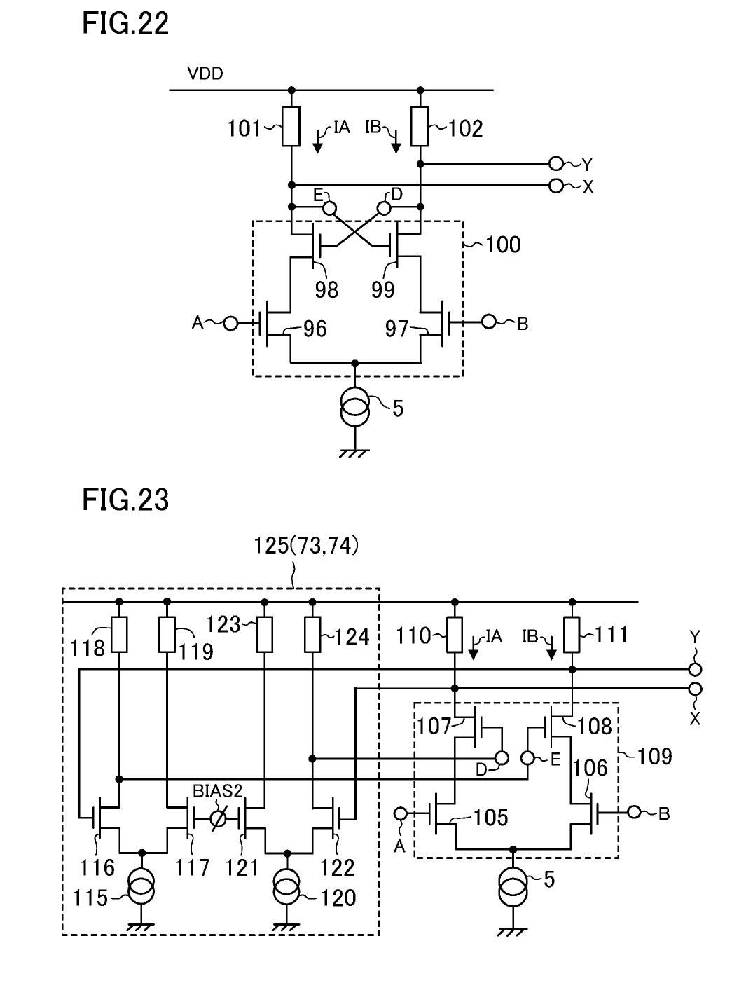

FIG. 22 also shows a variation of the example circuit of FIG. 19 in which the bypass circuit including the NMOS transistors 83 and 85 of FIG. 19 is removed. In a current control circuit 100 of FIG. 22, NMOS transistors 96, 97, 98, and 99 correspond to the NMOS transistors 80, 81, 82, and 84 of FIG. 19. Load elements 101 and 102 of FIG. 22 correspond to the load elements 86 and 87 of FIG. 19. As described above, at cross points of currents IA and IB, the currents IA and IB are limited, so that the sum values of the currents IA and IB are decreased. In this case, a constant current source 5 actually includes a MOS transistor etc. and therefore has a finite output impedance, and therefore, the amounts of the currents come into an equilibrium state. Also in this case, the control circuit 100 has voltage or current waveforms similar to those of FIGS. 17A-17D at terminals thereof, i.e., cross points of voltages of output terminals X and Y are shifted to a higher value.

When it is desirable to increase the amount of the shift of the cross point, a delay circuit is used. FIG. 23 shows an example in which a delay circuit is connected to the current control circuit of FIG. 22. In FIG. 23, the delay circuit 125 includes constant current sources 115 and 120, NMOS transistors 116, 117, 121, and 122, and load elements 118, 119, 123, and 124. Thus, the delay circuit 125 includes two of the typical CML circuit configurations of FIG. 10B. Signals of output terminals X and Y and a DC value BIAS2 are input to input terminals of the delay circuit 125. Outputs of the delay circuit 125 are connected to control terminals D and E. As a result, the amount of a delay is increased so that the amount of a shift of cross points of final voltages of the output terminals X and Y is increased. In a current control circuit 109 of FIG. 23, NMOS transistors 105, 106, 107, and 108 correspond to the NMOS transistors 96, 97, 98, and 99 of FIG. 22. Load elements 110 and 111 of FIG. 23 correspond to the load elements 101 and 102 of FIG. 22.

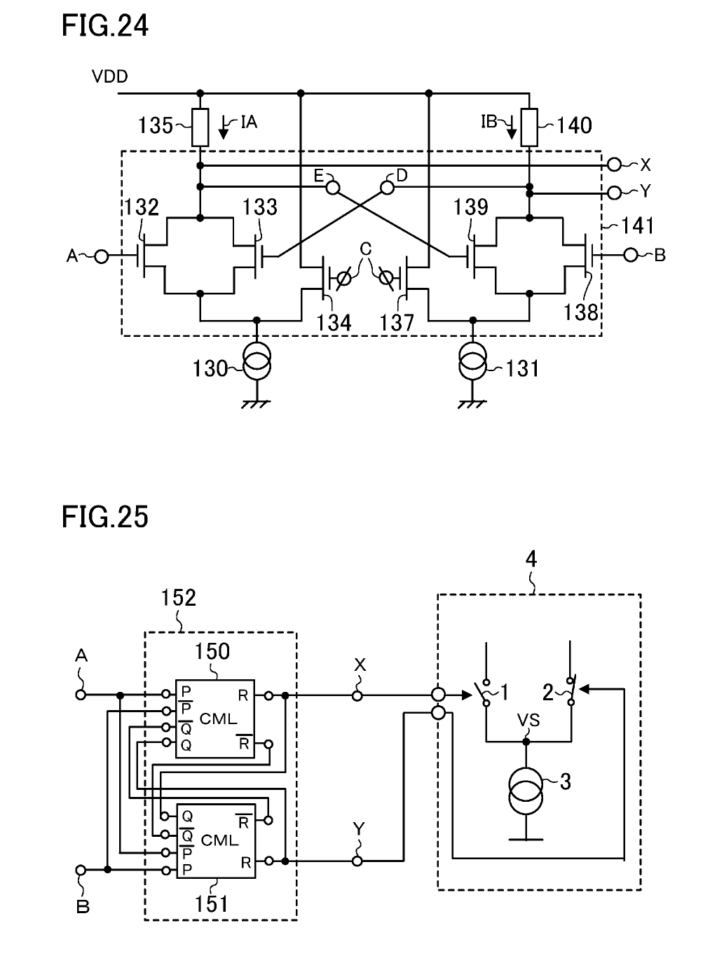

FIG. 24 shows an example circuit including a logic unit having the NOR function. In FIG. 24, a dotted-line portion 141 indicates a current control circuit. Load elements 135 and 140 are connected between the current control circuit 141 and a power supply. NMOS transistors 132 and 133 and NMOS transistors 138 and 139 correspond to those of FIG. 12B. Constant current sources 130 and 131 are connected to the respective corresponding portions having the NOR function. Input terminals A and B are connected to gate terminals of the NMOS transistors 132 and 138, respectively. Output terminals Y and X are connected to control terminals D and E, respectively, which are gate terminals of the NMOS transistors 133 and 139. Note that a delay circuit may be provided between the control terminals D and E and the output terminals Y and X. NMOS transistors 134 and 137 are bypass circuits for causing a current to bypass the load elements 135 and 140. A DC value between the high and low levels of voltages of the control terminals D and E is input to gate terminals of the NMOS transistors 134 and 137. The circuit having such a configuration includes the logic units having the NOR function, and therefore, have, at terminals thereof, voltage or current waveforms similar to those of FIGS. 18A-18D. Therefore, cross points of voltages of the output terminals X and Y are shifted to a lower value. Note that, as indicated by this example circuit, a current control circuit may require two or more constant current sources.

According to the third embodiment, a differential switch drive circuit can be configured using a CML circuit (a circuit in which a current of a constant current source is controlled using a plurality of control terminals so that currents flow through load elements to generate output voltages), which is suitable for high-speed operation. Therefore, a plurality of switch elements included in the differential switch circuit can be prevented from being simultaneously off, whereby response characteristics of the output of the differential switch circuit can be improved. As in the second embodiment, the amount of the shift of the cross point of the output voltages can be changed, depending on the amount of the delay of the delay circuit, leading to an increase in design flexibility.

Note that the configurations of FIGS. 19-24 are merely examples. The logic unit may have the configurations shown in FIGS. 11A-11C and FIGS. 12A-12C or other configurations having the same function. The delay circuit may have any other configuration that provides a delay amount, instead of the configuration of FIGS. 10A and 10B. Although the bypass circuit is used to cause a current to bypass the load element in the above example, the bypass circuit may be removed if an element having a finite output impedance can be used to secure a stable operation. Although a DC value is input to the gate terminal of the MOS transistor of the bypass circuit, the input is not limited to a DC value. Alternatively, any signal that is controlled to bypass the load element connected to the output may be applied.

### Fourth Embodiment

FIG. 25 is a diagram showing a configuration according to a fourth embodiment of the present disclosure. In FIG. 25, a differential switch circuit 4 has the same conventional configuration as that of the first embodiment. A differential switch drive circuit 152 has input terminals A and B to which non-inverted and inverted signals having opposite phases are input. The differential switch drive circuit 152 includes first and second CML circuits 150 and 151 having differential input/differential output terminals having the NAND or NOR function. The input terminal A is connected to a non-inverted input terminal of a signal P of the first CML circuit 150, and the input terminal B is connected to an inverted input terminal of the signal P of the first CML circuit 150. The input terminal B is connected to a non-inverted input terminal of a signal P of the second CML circuit 151, and the input terminal A is connected to an inverted input terminal of the signal P of the second CML circuit 151. Non-inverted and inverted output terminals of a signal R of the first CML circuit 150 are connected to non-inverted and inverted input terminals, respectively, of a signal Q of the second CML circuit 151. Non-inverted and inverted output terminals of a signal R of the second CML circuit 151 are connected to non-inverted and inverted input terminals, respectively, of a signal Q of the first CML circuit 150. A non-inverted output of the signal R of the first CML circuit 150 is connected to an output terminal X, and a non-inverted output of the signal R of the second CML circuit 151 is connected to an output terminal Y. The output terminals X and Y are connected to the differential switch circuit 4.

With such a configuration, cross points of voltages of the output terminals X and Y are shifted from the middle point of the high and low levels of the output values. The principle of operation of this embodiment is based on the third embodiment. Although, in this embodiment, a circuit delay occurring in the CML circuits 150 and 151 themselves is used, a delay circuit may be additionally provided as in the third embodiment. Although, in this embodiment, an output of one of the CML circuits is used to control the other CML circuit, the input signal itself may be delayed and controlled as in the second embodiment. Although, in this embodiment, the differential input/differential output CML circuit is used, the present disclosure is not limited to this. Alternatively, a similar function may be provided by additionally providing a configuration similar to those of the first to third embodiments.

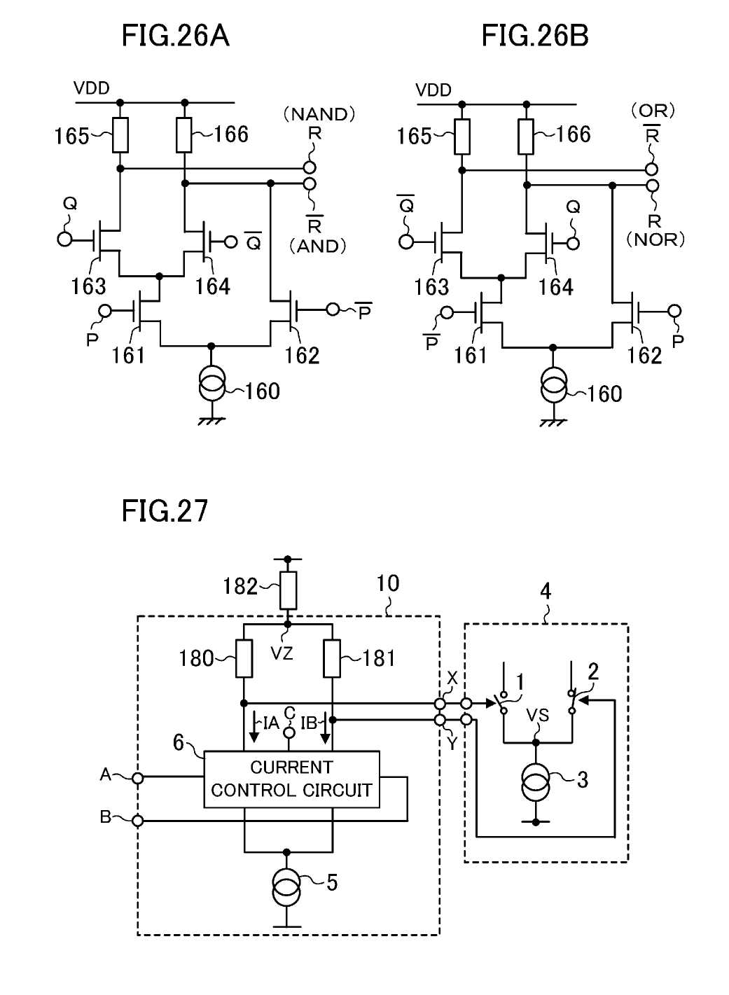

Examples of the first and second CML circuits 150 and 151 are shown in FIGS. 26A and 26B. FIG. 26A shows an example NAND circuit having a CML configuration having differential input/differential output terminals. FIG. 26B shows an example NOR circuit having a CML configuration having differential input/differential output terminals. In FIGS. 26A and 26B, the first and second CML circuits 150 and 151 have the same circuit configuration, except for assignment of terminals thereof. The first and second CML circuits 150 and 151 each include a constant current source 160, NMOS transistors 161 and 162 which have a common source terminal and are connected to the constant current source 160, and NMOS transistors 163 and 164 which have a common source terminal connected to a drain terminal of the NMOS transistor 161. An end of a load element 165 connected to a power supply is connected to a drain terminal of the NMOS transistor 163. Drain terminals of the NMOS transistors 164 and 162 are connected together and are connected to an end of the load element 166 connected to the power supply. In the NAND configuration of FIG. 26A, a non-inverted input of a signal P is input to a gate terminal of the NMOS transistor 161, an inverted input of the signal P is input to a gate terminal of the NMOS transistor 162, a non-inverted input of a signal Q is input to a gate terminal of the NMOS transistor 163, and an inverted input of the signal Q is input to a gate terminal of the NMOS transistor 164. A connection point between the drain terminal of the NMOS transistor 163 and the load element 165 is used as a non-inverted output (a non-inverted output of a signal R) of the NAND, and a connection point between the drain terminals of the NMOS transistors 162 and 164 and the load element 166 is used as an inverted output (an AND output, an inverted output of the signal R) of the NAND.

In the NOR configuration of FIG. 26B, an inverted input of a signal P is input to a gate terminal of the NMOS transistor 161, a non-inverted input of the signal P is input to a gate terminal of the NMOS transistor 162, an inverted input of a signal Q is input to a gate terminal of the NMOS transistor 163, and a non-inverted input of the signal Q is input to a gate terminal of the NMOS transistor 164. A connection point between the drain terminal of the NMOS transistor 163 and the load element 165 is used as an inverted output (an OR output, an inverted output of a signal R) of the NOR, and a connection point between the drain terminals of the NMOS transistors 162 and 164 and the load element 166 is used as a non-inverted output (a non-inverted output of the signal R) of the NOR.

According to the fourth embodiment, a differential switch drive circuit can be configured using a CML circuit (a circuit in which a current of a constant current source is controlled using a plurality of control terminals so that currents flow through load elements to generate output voltages), which is suitable for high-speed operation. Therefore, a plurality of switch elements included in the differential switch circuit can be prevented from being simultaneously off, whereby response characteristics of the output of the differential switch circuit can be improved.

Note that the CML circuits 150 and 151 are not limited to the above example configurations. Alternatively, any other CML circuit that has the same function as that described above may be used. A plurality of CML circuits may be used to provide the same function as that described above.

### Fifth Embodiment

FIG. 27 is a diagram showing a configuration according to a fifth embodiment of the present disclosure. In FIG. 27, a differential switch circuit 4 has the same conventional configuration as that of the first and fourth embodiments. A dotted-line portion 10 indicates the differential switch drive circuit of the first to fourth embodiments. One end of a load element 182 is connected to a common node of load elements 180 and 181 connected to output terminals X and Y, and the other end of the load element 182 is connected to a reference potential.

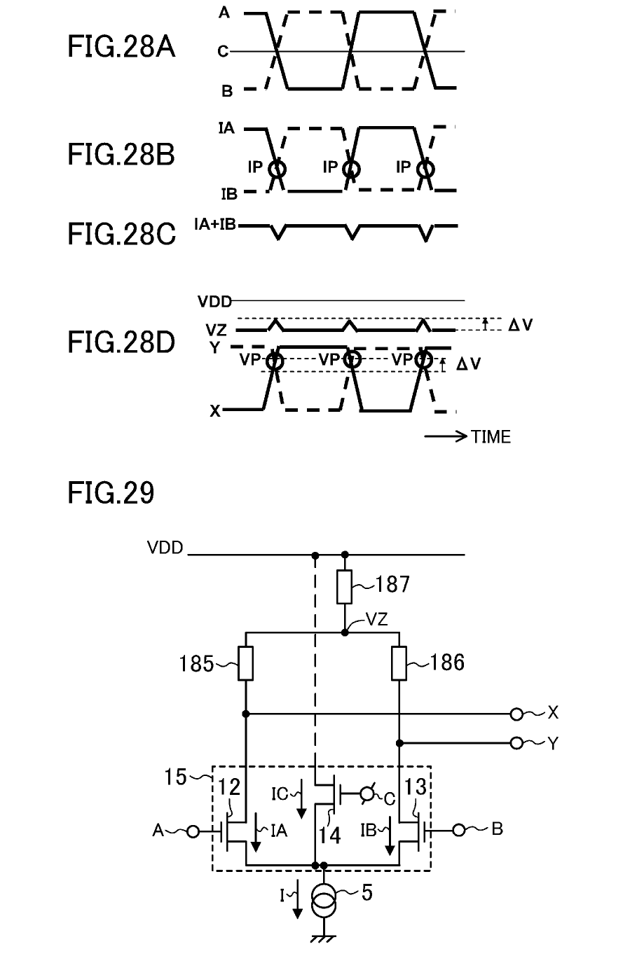

An operation of the configuration of the fifth embodiment of the present disclosure will be described with reference to voltage or current waveforms of terminals shown in FIGS. 28A, 28B, 28C, and 28D. FIG. 28A shows example voltage waveforms of terminals A, B, and C. FIG. 28B shows waveforms of currents IA and IB obtained by division controlled by a current control circuit 6. FIG. 28C shows a waveform of a current flowing through the load element 182. FIG. 28D shows a voltage waveform of a connection point VZ between the load elements 180, 181, and 182, and voltage waveforms of the output terminals X and Y of a differential switch drive circuit 10. As described in the other embodiments, if cross points IP of the currents IA and IB obtained by division controlled by the current control circuit 6 take a value which is shifted from the middle point of the high level and the low level to, for example, a current value which is lower than the middle point. The sum value of the currents IA and IB at the cross point IP takes a value which is lower than those of the other points as shown in FIG. 28C. As shown in FIG. 28D, voltages of the output terminals X and Y have an offset corresponding to a voltage of the connection point VZ, and the voltage of the connection point VZ increases as the sum value of the currents IA and IB at the current cross point IP decreases, and the cross point VP of the voltages of the output terminals X and Y is shifted by a change ΔV of the voltage of the connection point VZ. Thus, a larger shift amount can be obtained at the cross point than that which is obtained before the load element 182 is connected. By providing the output voltage with the offset voltage, the high level for driving the switch elements 1 and 2 of the differential switch circuit 4 can be reduced, and therefore, when a resistor etc. is connected to an output terminal of the differential switch circuit 4 to form, for example, a current steering DAC etc. so that a relatively large amplitude is output, sufficient saturation characteristics can be effectively secured for the switch elements 1 and 2.

FIG. 29 shows an example differential switch drive circuit according to the fifth embodiment of the present disclosure. The circuit configuration of FIG. 29 is based on that of FIG. 5. In FIG. 29, a load element 187 connected to a power supply is connected to a connection point VZ to which load elements 185 and 186 are both connected.

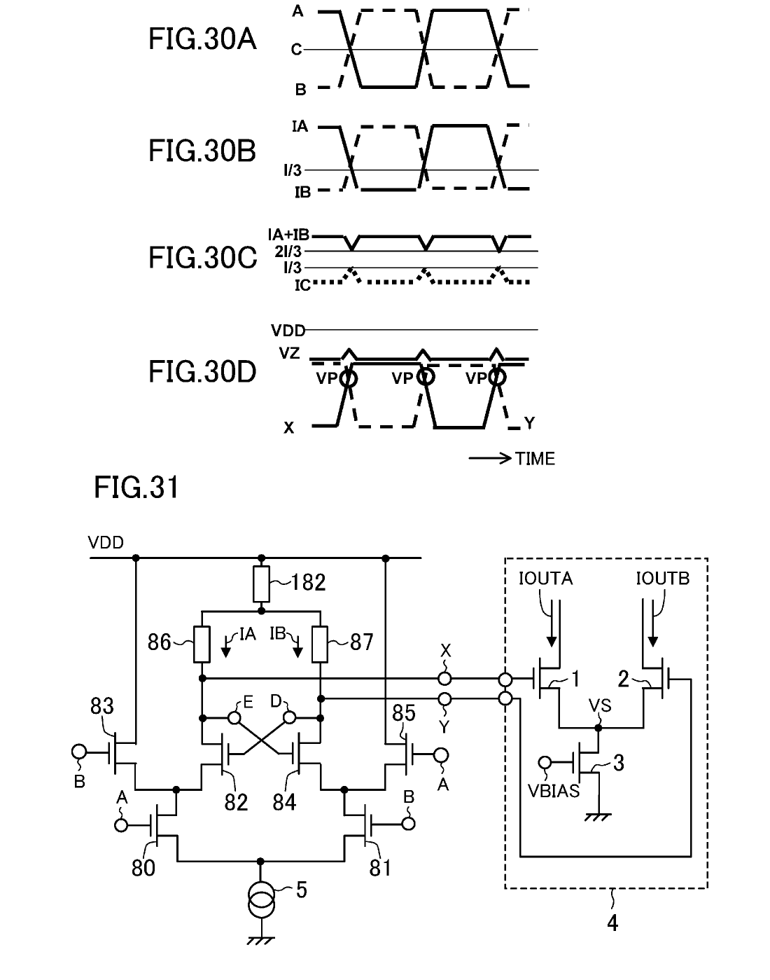

An operation of the differential switch drive circuit thus configured according to the fifth embodiment will be described with reference to voltage or current waveforms of terminals shown in FIGS. 30A, 30B, 30C, and 30D. FIG. 30A shows example voltage waveforms of terminals A, B, and C. FIG. 30B shows waveforms of currents IA and IB obtained by division controlled by a current control circuit 15. FIG. 30C shows a waveform of a current IA+IB flowing through the load element 187 and a waveform of a current IC flowing through an NMOS transistor 14. FIG. 30D shows a voltage waveform of the connection point VZ of the load elements 185, 186, and 187, and voltage waveforms of output terminals X and Y of the differential switch drive circuit. It is assumed that the differential switch drive circuit is operated under the same conditions as those of the first embodiment. The sum value of the currents IA and IB at cross points is 2I/3, where I is a current of a constant current source 5. Because the sum value of the currents IA and IB at the cross points is reduced by I/3, a voltage of the connection point VZ increases, and therefore, cross points VP of the voltage waveforms of the output terminals X and Y are shifted to a value which is higher by the voltage change ΔV of the connection point VZ.

FIG. 31 shows a configuration which is based on the circuit of FIG. 20. In this configuration, a load element 182 connected to a power supply is connected to a connection point to which load elements 86 and 87 are both connected.

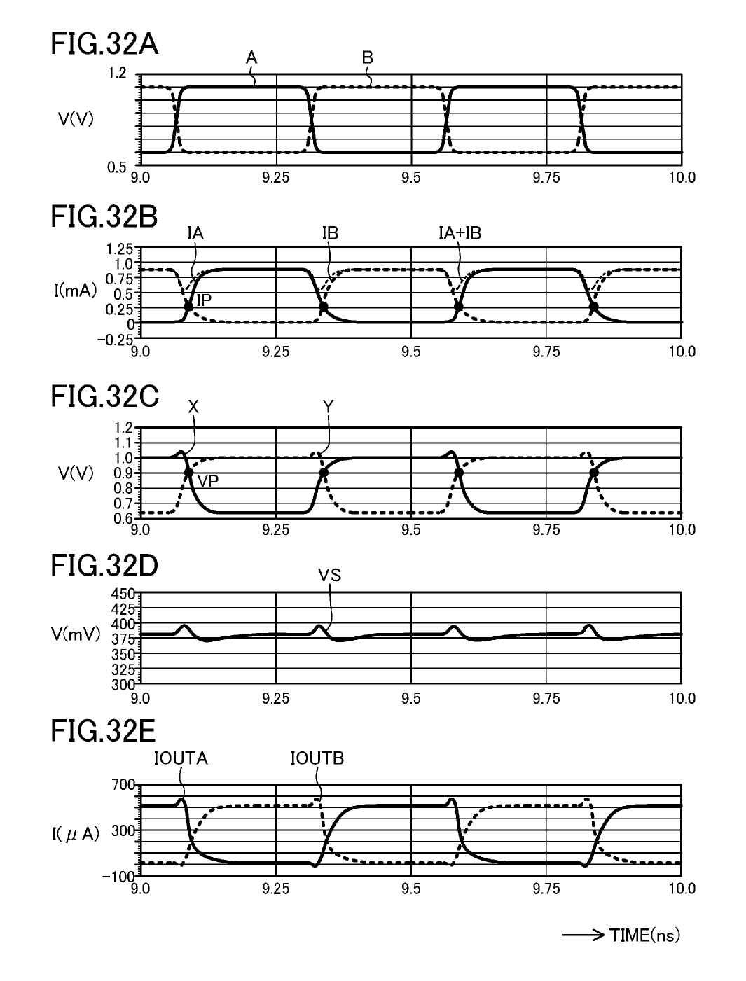

FIGS. 32A, 32B, 32C, 32D, and 32E show results of a simulation of voltage or current waveforms of terminals shown in FIG. 31. As shown in FIG. 32B, the cross points IP of the currents IA and IB are shifted to a value which is lower than in the conventional art, and the sum value of the currents IA and IB at the cross points is shifted to a value which is lower than during the steady state. As shown in FIG. 32C, the voltages of the output terminals X and Y have an offset due to the load element 182, and therefore, the cross points VP thereof are shifted toward the higher level. As shown in FIGS. 32D and 32E, a change at a node VS in the differential switch circuit 4 decreases, and transient response characteristics of waveforms of output currents IOUTA and IOUTB are improved.

According to the fifth embodiment, the configuration which allows the cross point of the output voltages to be shifted as described in the other embodiments, and the configuration in which the load elements are connected as described in this embodiment, are combined, whereby the amount of the shift of the cross point of the output voltages can be increased without an impairment in speed. Therefore, a plurality of switch elements included in the differential switch circuit can be prevented from being simultaneously off, whereby response characteristics of the output of the differential switch circuit can be improved.

### Sixth Embodiment

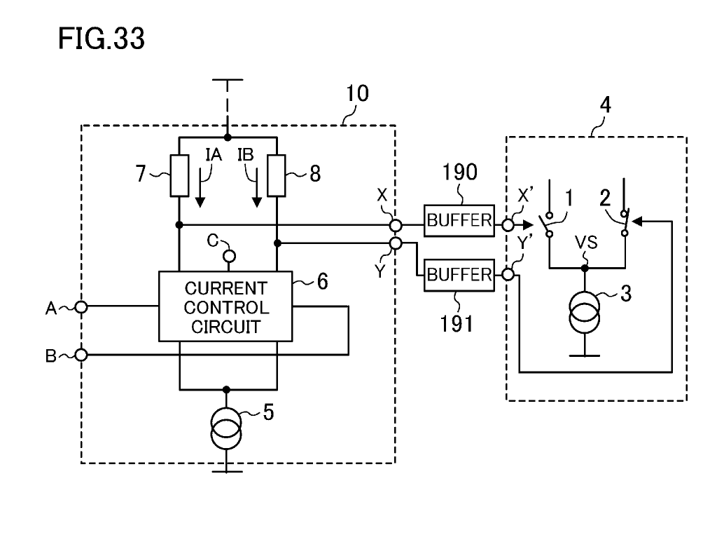

FIG. 33 is a diagram showing a configuration according to a sixth embodiment of the present disclosure. In FIG. 33, a differential switch circuit 4 has the same conventional configuration as that of the first, fourth, and fifth embodiments. A dotted-line portion 10 indicates the differential switch drive circuit of the first to fifth embodiments. In the other embodiments, the voltages which are generated by causing a current obtained by division controlled by the current control circuit to flow through the load elements, are connected directly to the differential switch circuit. Alternatively, as long as the differential switch drive circuit 10 can have outputs whose cross points are shifted, buffer circuits (source followers, inverters of a CML circuit, etc.) 190 and 191 may be provided between output terminals X and Y of the differential switch drive circuit 10 and input terminals X′ and Y′ of the differential switch circuit 4. In this case, switch elements 1 and 2 can be prevented from being simultaneously off, whereby an effect similar to that of the other embodiments can be achieved.

### Seventh Embodiment

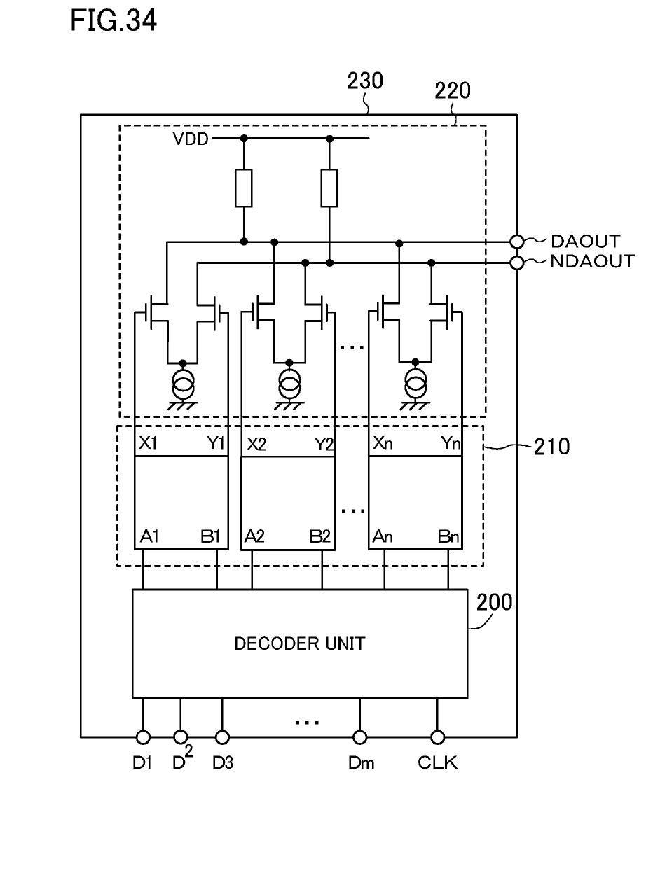

FIG. 34 is a diagram showing a configuration of a current steering DAC according to a seventh embodiment of the present disclosure. The current steering DAC 230 of FIG. 34 includes a decoder unit 200 connected to multiple-bit digital codes D1-Dm, a clock signal CLK etc., a differential switch drive circuit group 210 which includes differential switch drive circuits of any or a combination of those of the present disclosure and receives a signal decoded by the decoder unit 200, and a differential switch circuit group 220 which is connected to outputs of the differential switch drive circuit group 210. Outputs of the differential switch circuit group 220 are connected at a non-inverted output DAOUT and an inverted output NDAOUT, and are optionally connected to load elements.

In the current steering DAC 230 thus configured, the switch elements of the differential switch circuit group 220 are prevented from being simultaneously off, resulting in less distorted analog outputs. Because the CML circuit which controls the current of the constant current source at a plurality of control terminals and causes the controlled current to flow through load elements to generate output voltages, is applied to the differential switch drive circuit group 210, the current steering DAC 230 is suitable for high-speed operation.

Note that when the current steering DAC 230 of the present disclosure is mounted on silicon, the switch elements and the current sources in the differential switch circuit group 220 are preferably laid out as respective separate groups, i.e., a switch element group and a current source group. As a result, a layout can be achieved which is effective in reducing or preventing a deterioration in distortion due to current source mismatch, or crosstalk between an input control signal of the differential switch circuit group 220 and a bias voltage of the current source.

### Eighth Embodiment

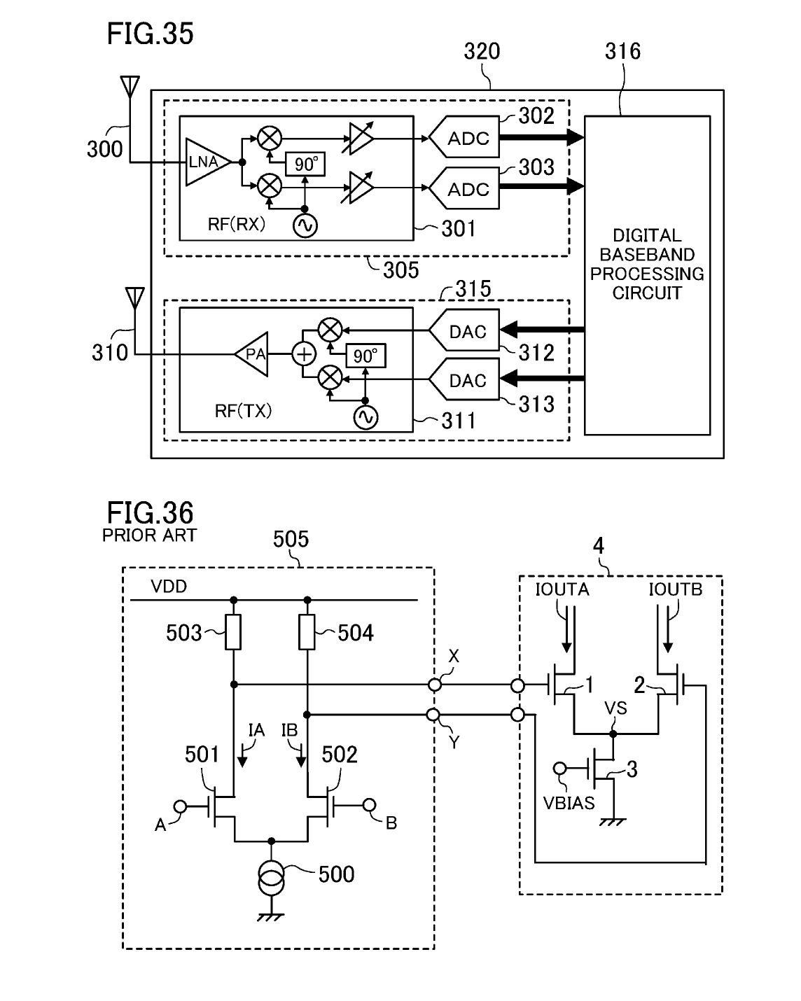

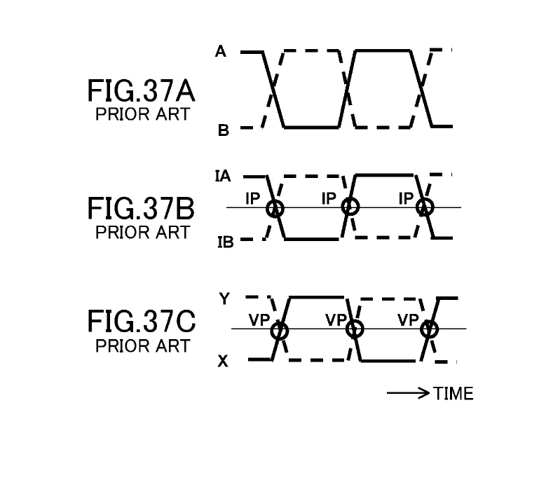

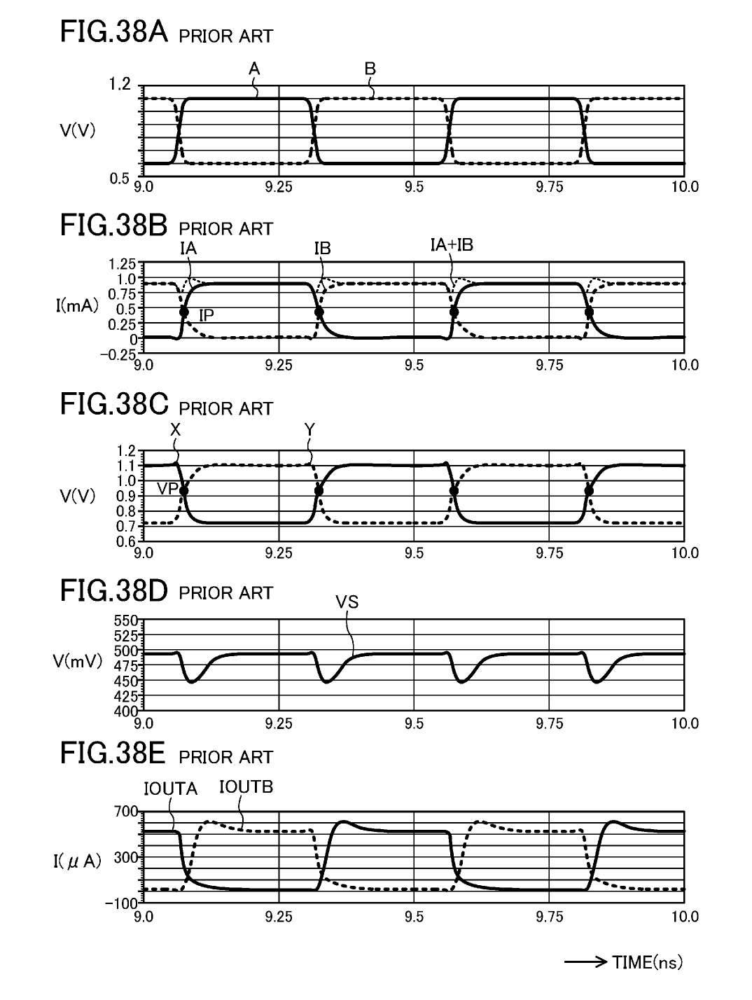

FIG. 35 is a diagram showing a configuration of a millimeter-wave communication system according to an eighth embodiment of the present disclosure. In a receiver system 305 of the communication system 320 of FIG. 35, signals received by a receiver antenna 300 are input via an RF receiver circuit 301 including a low-noise amplifier (LNA), a mixer, a VGA, etc. to analog-to-digital converters (ADCs) 302 and 303, which convert the signals into digital values. The digital values are input to and processed by a digital baseband processing circuit 316. In a transmitter system 315, signals digitally processed by the digital baseband processing circuit 316 are converted into analog signals by current steering DACs 312 and 313, and the resultant signals are transmitted via an RF transmitter circuit 311 including a mixer, a power amplifier (PA), etc. from a transmitter antenna 310 as radio waves.

In the communication system 320 thus configured, if the low-distortion and high-speed current steering DAC of the seventh embodiment of the present disclosure is used as the DACs 312 and 313, a system which requires transmission of a less-distorted signal having a signal band of the order of GHz, for use in millimeter-wave communication etc., can be provided.

Note that, in the differential switch drive circuit of each embodiment of the present disclosure, in order to drive the two input terminals of the differential switch circuit in a highly symmetrical manner, the circuit configurations between the input terminals A and B and the output terminals X and Y are preferably symmetrical as viewed from the respective output terminals. In the embodiments which include a bypass circuit which causes a current to bypass the load elements linked to the outputs, the bypass circuit is preferably configured to cause a current to eventually flow to a power supply to which the load elements are linked, in order to cause the total amount of currents flowing to the power supply to be constant, thereby reducing the amount of power supply noise which occurs during switching of control. Note that the load element may be a resistance element or an active element. A current may be caused to flow via a folded circuit to the load element connected to the output terminal. The number of control terminals is not limited to those described in the above embodiments, and a larger number of control terminals than those described in the above embodiments may be provided. Similarly, the number of constant current sources connected to the current control circuit is not limited to those described in the above embodiments, and a plurality of constant current sources may be connected. As to connection to the differential switch circuit, when a plurality of switch elements in the differential switch circuit each include an NMOS transistor, the signals of the output terminals of the differential switch drive circuit are preferably those whose cross points are shifted to a higher value in order to prevent the switch elements of the differential switch circuit from being simultaneously off. When the switch elements each include a PMOS transistor, signals whose cross points are shifted to a lower value is preferable.

The MOS transistors in each of the above-described example circuit configurations may be replaced with other active elements, such as a bipolar transistor etc. Moreover, NMOS transistors may be replaced with PMOS transistors, or vice versa, where the power supply and the ground are interchanged.

Note that the circuit connected to the input terminals of the differential switch drive circuit of the present disclosure is preferably a CML circuit, and the voltage amplitudes of signals applied to the input terminals are preferably smaller than one between the power supply and the ground, for the purpose of high-speed operation of the differential switch drive circuit of the present disclosure.

Obviously, it will be understood that a combination of the embodiments or a combination of a part of the functions which has a feature of the present disclosure, and a variation in which, for example, a resistor, a cascode-connected MOS transistor, etc. is provided at some point in a path in a portion to which a transistor or a current source is directly connected in the specification and drawings, are encompassed by the present disclosure as long as the electrical connection relationship of the present disclosure and a feature of the present disclosure are provided.

As described above, the present disclosure improves speed and response characteristics of a differential switch circuit, and therefore, is suitably used in application circuits, such as a high-speed communication system etc.

What is claimed is:

1. A differential switch drive circuit for driving a differential switch circuit including a first and a second switch element each having a terminal connected to a current source, comprising:
a current source;
at least one pair of transistors having a pair of differential input terminals, a pair of differential output terminals, and a common connection node connected to the current source; and
load elements each connected to a corresponding one of the pair of differential output terminals,
wherein
signal voltages are applied to the pair of differential input terminals, and output voltages having a steady state in which the output voltages each take a respective one of two substantially constant values and a transient state in which the output voltages transition between the two substantially constant values, are output to the pair of differential output terminals, depending on voltages of the pair of differential input terminals, and
currents flowing through the at least one pair of transistors are controlled so that the sum of values of currents flowing through the load elements during the steady state of the differential output voltages is different from the sum of values of currents flowing through the load elements during the transient state of the differential output voltages.

2. The differential switch drive circuit of claim 1, wherein
the current source is a MOS transistor having a source terminal connected to a fixed voltage, a gate terminal to which a bias voltage is supplied, and a drain terminal connected to the common connection node.

3. The differential switch drive circuit of claim 1, further comprising:
a bypass circuit connected to the at least one pair of transistors;
wherein
the currents flowing through the at least one pair of transistors are controlled based on a control signal supplied via a control terminal.

4. The differential switch drive circuit of claim 3, wherein
the bypass circuit includes a current path having a terminal connected to the common connection node of the at least one pair of transistors, and a gate terminal to which a dc voltage within a dc input range of a signal applied to the pair of input terminals is applied.

5. The differential switch drive circuit of claim 1, wherein
the at least one pair of transistors include a first, a second, a third, and a fourth MOS transistor,
a non-inverted input terminal is connected to a gate terminal of the first MOS transistor, and a source terminal of the third MOS transistor is connected to a drain terminal of the first MOS transistor,
an inverted input terminal is connected to a gate terminal of the second MOS transistor, and a source terminal of the fourth MOS transistor is connected to a drain terminal of the second MOS transistor,
the first and second MOS transistors have a common source terminal, and the current source is connected to the common source terminal,
an inverted output terminal and a first load element are connected to a drain terminal of the third MOS transistor,
a non-inverted output terminal and a second load element are connected to a drain terminal of the fourth MOS transistor, and
a signal which rises later than a signal of the non-inverted input terminal is input to a gate terminal of the third MOS transistor, and a signal which rises later than a signal of the inverted input terminal is input to a gate terminal of the fourth MOS transistor.

6. The differential switch drive circuit of claim 5, wherein
a non-inverted signal obtained by delaying a signal applied to the non-inverted input terminal is applied to the gate terminal of the third MOS transistor, and
an inverted signal obtained by delaying a signal applied to the inverted input terminal is applied to the gate terminal of the fourth MOS transistor.

7. The differential switch drive circuit of claim 1, wherein
the at least one pair of transistors include a first, a second, a third, and a fourth MOS transistor,
a non-inverted input terminal is connected to a gate terminal of the first MOS transistor, and a source terminal of the third MOS transistor is connected to a drain terminal of the first MOS transistor,
an inverted input terminal is connected to a gate terminal of the second MOS transistor, and a source terminal of the fourth MOS transistor is connected to a drain terminal of the second MOS transistor,
the first and second MOS transistors have a common source terminal, and the current source is connected to the common source terminal,
an inverted output terminal and a first load element are connected to a drain terminal of the third MOS transistor,
a non-inverted output terminal and a second load element are connected to a drain terminal of the fourth MOS transistor, and
a signal is applied via the non-inverted output terminal to a gate terminal of the third MOS transistor, and a signal is applied via the inverted output terminal to a gate terminal of the fourth MOS transistor.

8. The differential switch drive circuit of claim 1, wherein
the at least one pair of transistors include a first, a second, a third, a fourth, a fifth, and a sixth MOS transistor,
a non-inverted input terminal is connected to a gate terminal of the first MOS transistor, and source terminals of the third and fifth MOS transistors are connected to a drain terminal of the first MOS transistor,
an inverted input terminal is connected to a gate terminal of the second MOS transistor, and source terminals of the fourth and sixth MOS transistors are connected to a drain terminal of the second MOS transistor,
the first and second MOS transistors have a common source terminal, and the current source is connected to the common source terminal,
an inverted output terminal and a first load element are connected to a drain terminal of the third MOS transistor, and
a non-inverted output terminal and a second load element are connected to a drain terminal of the fourth MOS transistor.

9. The differential switch drive circuit of claim 8, wherein
a gate terminal of the fifth MOS transistor is connected to the inverted input terminal, and a gate terminal of the sixth MOS transistor is connected to the non-inverted input terminal.

10. The differential switch drive circuit of claim 1, wherein
the at least one pair of transistors include a first, a second, a third, and a fourth MOS transistor,
a non-inverted input terminal is connected to a gate terminal of the first MOS transistor, and an inverted input terminal is connected to a gate terminal of the second MOS transistor,
the first and third MOS transistors have a common source terminal and a common drain terminal, a first current source is connected to the common source terminal, and a first load element and an inverted output terminal are connected to the common drain terminal,
the second and fourth MOS transistors have a common source terminal and a common drain terminal, a second current source is connected to the common source terminal, and a second load element and a non-inverted output terminal are connected to the common drain terminal, and
a signal which rises later than a signal applied to the non-inverted input terminal is input to a gate terminal of the third MOS transistor, and a signal which rises later than a signal applied to the inverted input terminal is input to a gate terminal of the fourth MOS transistor.

11. The differential switch drive circuit of claim 1, wherein
the at least one pair of transistors include a first, a second, a third, a fourth, a fifth, and a sixth MOS transistor,
a non-inverted input terminal is connected to a gate terminal of the first MOS transistor, and an inverted input terminal is connected to a gate terminal of the second MOS transistor,
the first, third, and fifth MOS transistors have a common source terminal, the first and third MOS transistors have a common drain terminal, a first current source is connected to the common source terminal of the first, third, and fifth MOS transistors, a first load element and an inverted output terminal are connected to the common drain terminal of the first and third MOS transistors, and a signal is input via a non-inverted output terminal to a gate terminal of the third MOS transistor, and
the second, fourth, and sixth MOS transistors have a common source terminal, the second and fourth MOS transistors have a common drain terminal, a second current source is connected to the common source terminal of the second, fourth, and sixth MOS transistors, a second load element and the non-inverted output terminal are connected to the common drain terminal of the second and fourth MOS transistors, and a signal is input via the inverted output terminal to a gate terminal of the fourth MOS transistor.

12. A differential switch drive circuit for driving a differential switch circuit including a first and a second switch element each having a terminal connected to a current source, comprising:
a first current-mode logic circuit including a first pair of input terminals to which a first non-inverted signal and a first inverted signal are supplied, a second pair of input terminals to which a second non-inverted signal and a second inverted signal are supplied, a current source, a pair of output terminals through which a NAND and an AND logic signal are output, depending on signals applied to the first and second pairs of input terminals, and load elements each connected to a corresponding one of the pair of output terminals; and
a second current-mode logic circuit including a first pair of input terminals to which a first non-inverted signal and a first inverted signal are supplied, a second pair of input terminals to which a second non-inverted signal and a second inverted signal are supplied, a current source, a pair of output terminals through which a NAND and an AND logic signal are output, depending on signals applied to the first and second pairs of input terminals, and load elements each connected to a corresponding one of the pair of output terminals,
wherein
the NAND and AND logic outputs of the second current-mode logic circuit are input to the second pair of input terminals of the first current-mode logic circuit,
the NAND and AND logic outputs of the first current-mode logic circuit are input to the second pair of input terminals of the second current-mode logic circuit,
differential input signals having opposite phases are applied to the first pair of input terminals of the first current-mode logic circuit and the first pair of input terminals of the second current-mode logic circuit, and
the NAND logic output terminal of the first current-mode logic circuit serves as an inverted output terminal, and the NAND logic output terminal of the second current-mode logic circuit serves as a non-inverted output terminal.

13. A differential switch drive circuit for driving a differential switch circuit including a first and a second switch element each having a terminal connected to a current source, comprising:
a first current-mode logic circuit including a first pair of input terminals to which a first non-inverted signal and a first inverted signal are supplied, a second pair of input terminals to which a second non-inverted signal and a second inverted signal are supplied, a current source, a pair of output terminals through which a NOR and an OR logic signal are output, depending on signals applied to the first and second pairs of input terminals, and load elements each connected to a corresponding one of the pair of output terminals; and
a second current-mode logic circuit including a first pair of input terminals to which a first non-inverted signal and a first inverted signal are supplied, a second pair of input terminals to which a second non-inverted signal and a second inverted signal are supplied, a current source, a pair of output terminals through which a NOR and an OR logic signal are output, depending on signals applied to the first and second pairs of input terminals, and load elements each connected to a corresponding one of the pair of output terminals,
wherein
the NOR and OR logic outputs of the second current-mode logic circuit are input to the second pair of input terminals of the first current-mode logic circuit,
the NOR and OR logic outputs of the first current-mode logic circuit are input to the second pair of input terminals of the second current-mode logic circuit,
differential input signals having opposite phases are applied to the first pair of input terminals of the first current-mode logic circuit and the first pair of input terminals of the second current-mode logic circuit, and
the NOR logic output terminal of the first current-mode logic circuit serves as an inverted output terminal, and the NOR logic output terminal of the second current-mode logic circuit serves as a non-inverted output terminal.

14. The differential switch drive circuit of claim 1, wherein
a buffer circuit is added to each of the pair of output terminals of the at least one pair of transistors, to drive the differential switch circuit.

15. The differential switch drive circuit of claim 1, wherein
one end of each of the first and second load elements is connected to a corresponding one of the pair of output terminals, the other end of each of the first and second load elements is connected to a common node, one end of a third load element is connected to the common node, and the other end of the third load element is connected to a power supply terminal.

16. A current steering digital-to-analog converter comprising:
a decoder circuit configured to decode a digital signal;
a plurality of differential switch circuits; and
a plurality of differential switch drive circuits each configured to drive a corresponding one of the plurality of differential switch circuits,
wherein
the current steering digital-to-analog converter adds currents each selected by a corresponding one of the plurality of differential switch circuits together to output an analog quantity, and
each of the plurality of differential switch drive circuits includes a current control circuit to which a non-inverted and an inverted input terminal to which a signal decoded by the decoder circuit is applied, a non-inverted and an inverted output terminal, a first and a second load element connected to the inverted and non-inverted output terminals, respectively, and a current source, are connected, and the current control circuit controls currents flowing through the two load elements based on input signals applied to the non-inverted and inverted input terminals so that a point where output voltages of each of the differential switch drive circuits connected to a pair of input terminals of a corresponding one of the plurality of differential switch circuits are equal to each other, is substantially shifted from the middle voltage of a dc output voltage range of the output voltages.

17. The current steering digital-to-analog converter of claim 16, wherein
the plurality of differential switch drive circuits each include
a current source, and
a pair of transistors having a non-inverted and an inverted input terminal to which outputs of the decoder circuit are input, a non-inverted and an inverted output terminal, and a common connection node connected to the current source, and
output voltages having a steady state in which the output voltages each take a respective one of two substantially constant values and a transient state in which the output voltages transition between the two substantially constant values, are output to the non-inverted and inverted output terminals, depending on voltages of the non-inverted and inverted signals, and currents flowing through the pair of transistors are controlled so that the sum of values of currents flowing through the load elements during the steady state of the differential output voltages is different from the sum of values of currents flowing through the load elements during the transient state of the differential output voltages.
